(19) United States
(12) Patent Application Publication
(10) Pub. No.: US 2025/0234530 A1
(43) Pub. Date: Jul. 17, 2025

(54) MEMORY DEVICE AND METHOD FOR FORMING THE SAME

(71) Applicant: TAIWAN SEMICONDUCTOR MANUFACTURING COMPANY, LTD., Hsinchu (TW)

(72) Inventors: Ji-Kuan LEE, Taichung City (TW); Min-Chiao YEH, Taoyuan City (TW); Yao-Jen YANG, Hsinchu County (TW); Gu-Huan LI, Hsinchu County (TW); Chen-Wei LIANG, Taipei City (TW)

(73) Assignee: TAIWAN SEMICONDUCTOR MANUFACTURING COMPANY, LTD., Hsinchu (TW)

(21) Appl. No.: 18/415,192

(22) Filed: Jan. 17, 2024

(51) Int. Cl. H10B 20/25

(52) U.S. Cl. CPC H10B 20/25

(57) ABSTRACT

A method includes forming a first select transistor of a first one-time programmable (OTP) memory bit cell over a substrate, wherein the first select transistor is of a first conductivity type; forming a first anti-fuse transistor of the first OTP memory bit cell over the substrate, wherein the first anti-fuse transistor is of a second conductivity type opposite to the first conductivity type; forming a bit line over the substrate, wherein the bit line is electrically coupled to a source/drain terminal of the first select transistor.

### BACKGROUND

Integrated circuits (ICs) sometimes include one-time-programmable (“OTP”) memory elements to provide non-volatile memory (“NVM”) in which data are not lost when the IC is powered off. One type of NVM includes an anti-fuse bit integrated into an IC by using a layer of dielectric material (oxide, etc.) connected to other circuit elements. To program an anti-fuse bit, a programming electric field is applied across the dielectric material layer to sustainably alter (e.g., break down) the dielectric material, thus decreasing the resistance of the dielectric material layer. Typically, to determine the status of an anti-fuse bit, a read voltage is applied across the dielectric material layer and a resultant current is read.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic circuit diagram for performing a programming operation to a memory device in accordance with some embodiments of the present disclosure.

FIGS. 1B, 7A, 7B, 8A, 9A, 10A, 11A, and 11B are schematic circuit diagrams of memory devices in accordance with some embodiments of the present disclosure.

FIGS. 1C, 1D, 1G, 1H, 7C, 7D, 8B, 8C, 9B, 9C, 10B, 10C, 11C, and 11D are top views of a memory device in accordance with some embodiments of the present disclosure.

FIGS. 1E, 1F, and 1J illustrate cross-sectional views taken along line E-E′, line F-F′, line J-J′ as shown in FIGS. 1C and 1G.

FIG. 1I illustrates a schematic diagram of a semiconductor structure having a connected poly on oxide definition (OD) edge (CPODE) structure to separate two different program devices in accordance with some embodiments of the present disclosure.

FIGS. 2A-2C illustrate different layout arrangements of memory devices in accordance with some embodiments of the present disclosure.

FIGS. 3A-6C illustrate schematic views of intermediate stages in the manufacturing of a memory device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present disclosure are directed to, but not otherwise limited to, a fin-like field-effect transistor (FinFET) device. The FinFET device, for example, may be a complementary metal-oxide-semiconductor (CMOS) device including a P-type metal-oxide-semiconductor (PMOS) FinFET device and an N-type metal-oxide-semiconductor (NMOS) FinFET device. The following disclosure will continue with one or more FinFET examples to illustrate various embodiments of the present disclosure. It is understood, however, that the application should not be limited to a particular type of device, except as specifically claimed.

The fins may be patterned by any suitable method. For example, the fins may be patterned using one or more photolithography processes, including double-patterning or multi-patterning processes. The double-patterning or the multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Anti-fuses in memory cells use NMOS transistors, leading to an unbalanced ratio of PMOS and NMOS transistors in the bit cell arrays. Additionally, in MOSFET designs, transistors share a common substrate. When a breakdown occurs in one MOSFET, it can lead to significant substrate leakage, affecting nearby non-programming bit cells. This leakage can compromise the integrity of other memory cells and reduce overall programming efficiency. Furthermore, to increase the success rate of programming, two bit cells were written in different banks. While this method improved programming success rates, it added complexity to the memory array's architecture.

Therefore, the present disclosure in various embodiments provides a memory bit cell with an additional PMOS transistor therein. This structure with both NMOS and PMOS transistors can introduce a balanced ratio of PMOS/NMOS in bit cell array, achieving a more balanced distribution of transistor types and enhancing the overall stability and uniformity of the memory cell's electrical characteristics. Additionally, the introduction of PMOS transistors can create multiple potential breakdown paths during the programming process, which in turn increases the likelihood of successful programming, as it provides alternative routes for breakdown if one path fails. Furthermore, in super-power-rail (SPR) processes, the connected poly on oxide definition (OD) edge (CPODE) structure can introduce in MOSFETs to isolate the substrate, mitigating leakage issues. This isolation not only prevents the substrate leakage on neighboring bit cells but also contributes to higher overall performance in SPR processes.

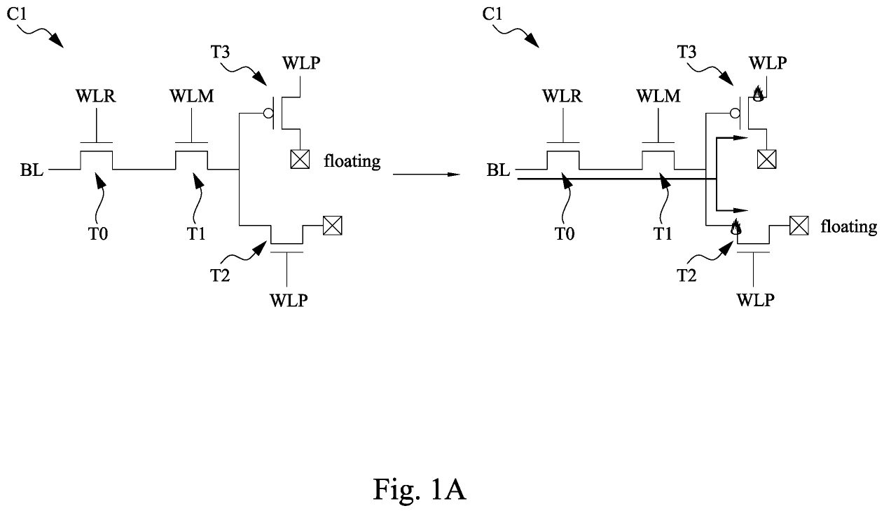

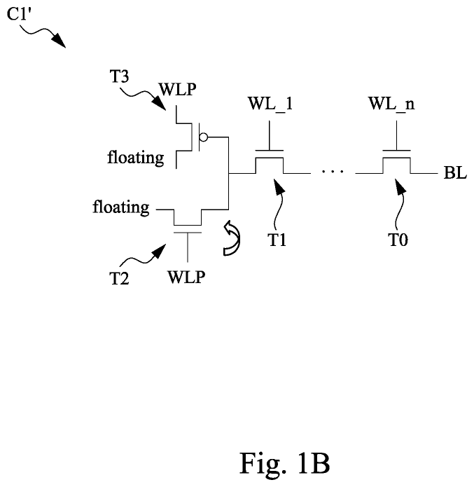

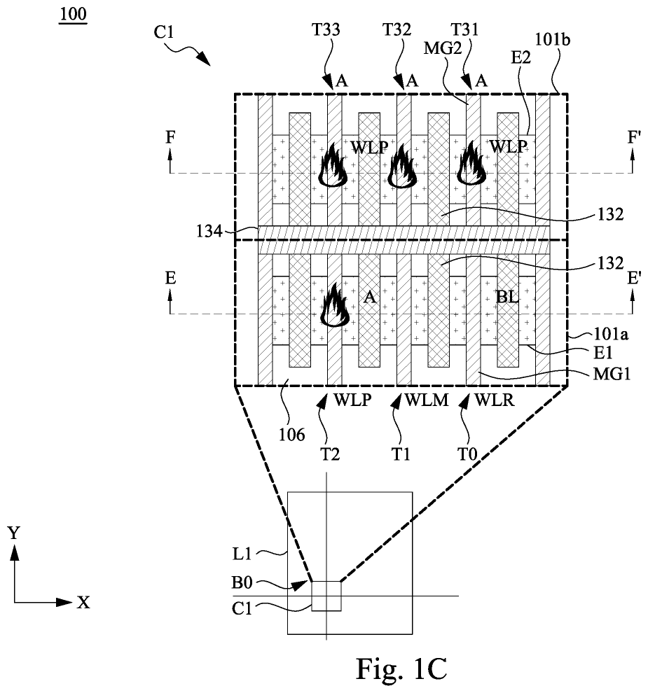

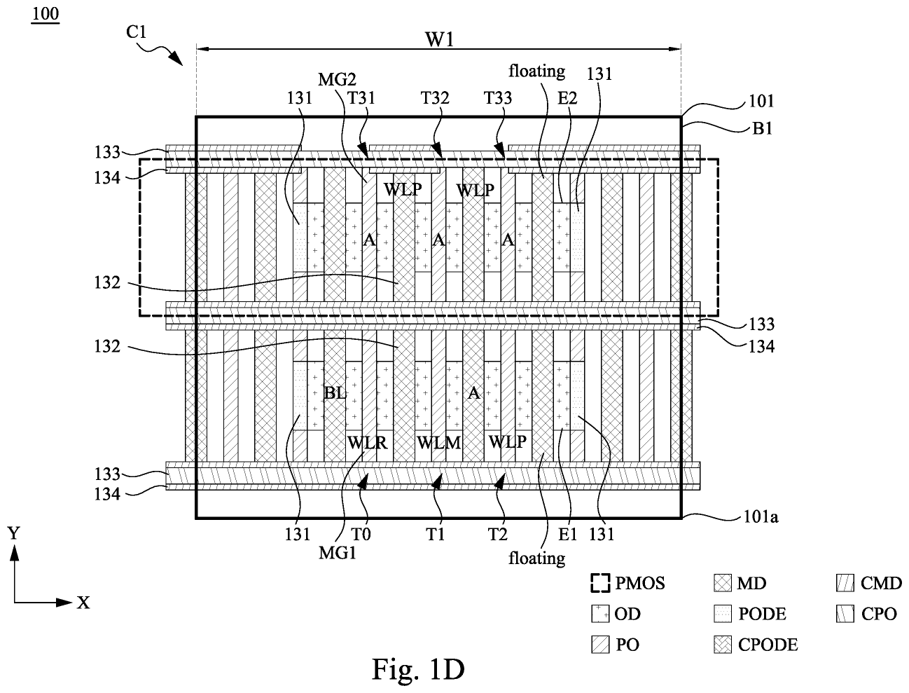

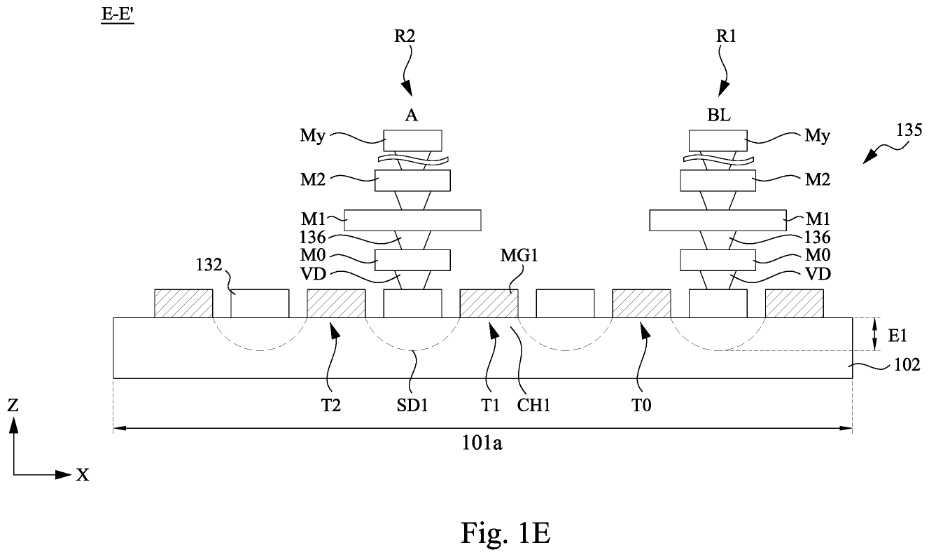

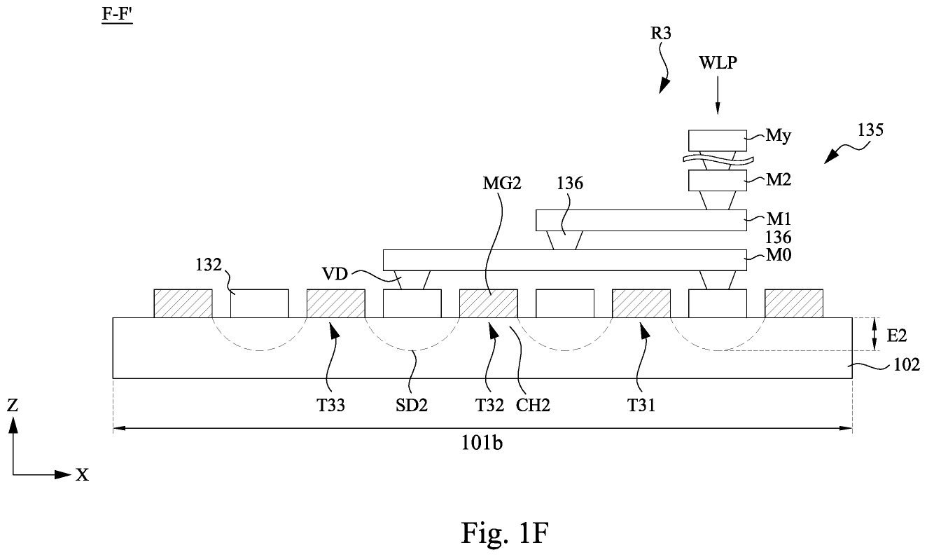

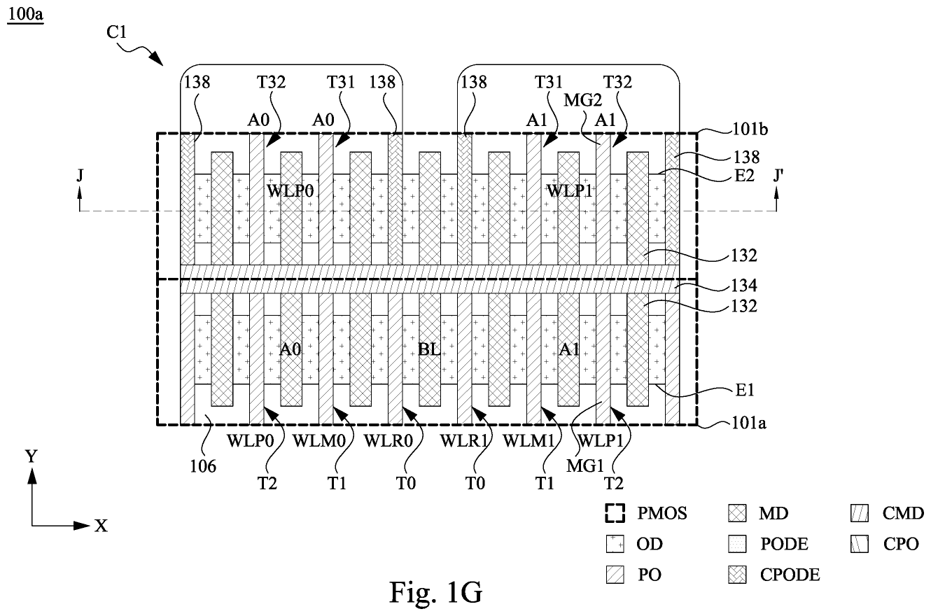

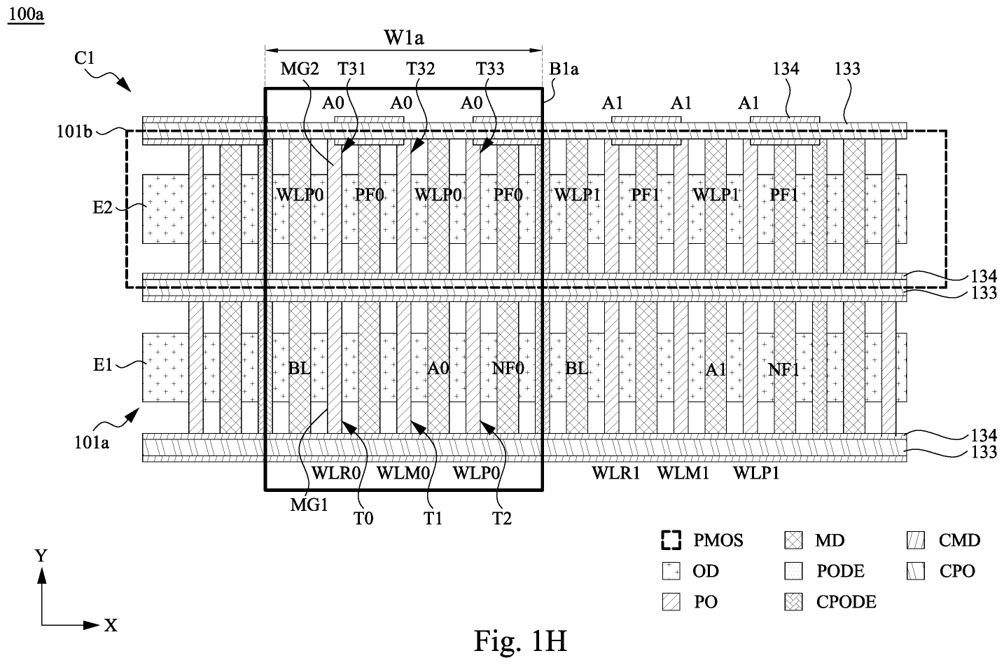

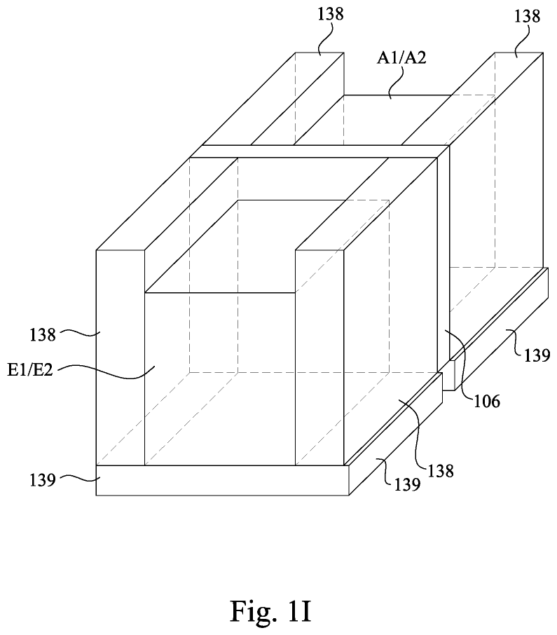

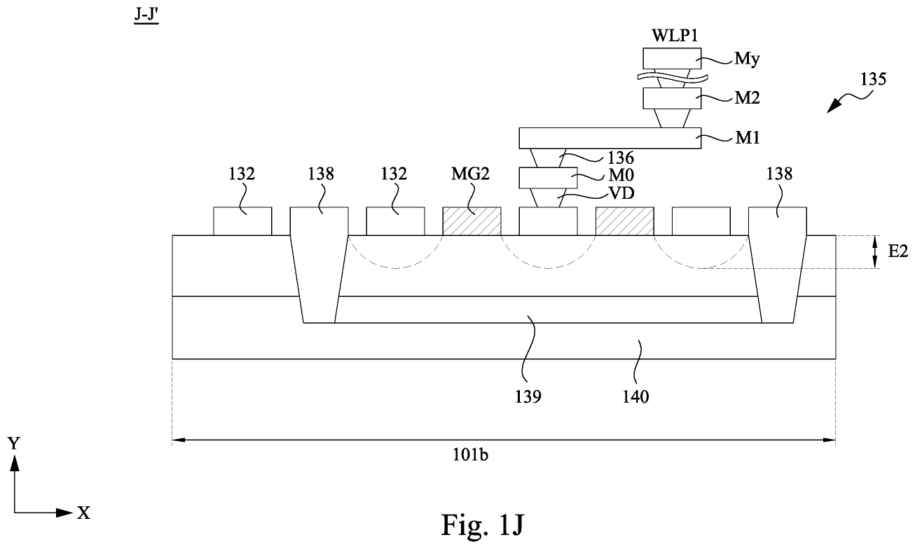

Reference is made to FIG. 1A. FIG. 1A illustrates a schematic circuit diagram for performing a programming operation to a memory device 100 in accordance with some embodiments of the present disclosure. As depicted in FIG. 1A, a memory device 100 may include an anti-fuse one-time programmable (OTP) memory cell C1, word lines WLR, WLM, and WLP, and a bit line BL. In some embodiments, the OTP memory cell C1 is a bit cell. The OTP memory cell C1 may include a first transistor T0, a second transistor T1, a third transistor T2, and a fourth transistor T3. In some embodiments, a gate of a transistor can be formed by laminating conductive layers on an insulating layer. In a programming operation, an insulating layer of the gate of the third transistor T2 and/or fourth transistor T3 may be destroyed. The first transistor T0 can serve as a switching element in order to select the OTP memory cell. In some embodiments, the first transistor T0 can be interchangeably referred to as a select transistor, and the third and fourth transistors can be interchangeably referred to as anti-fuse transistors or programming transistors.

The second transistor T1 can be used to relax the voltage stress among the first, third, and fourth transistors T0, T2, and T3. The second transistor T1 can manage the distribution of programming voltage of the OTP memory cell C1, ensuring that the first, third, and fourth transistors T0, T2, and T3 can receive an optimal voltage for programming without being exposed to excessive stress. In some embodiment, if the voltage provided by the word line WLR exceeds 0.96V, the insulating layer of the gate of the transistor T0 may be broken down. By mitigating the high voltage stress on the first, third, and fourth transistors T0, T2, and T3, the second transistor T1 can reduce the risk of unintended breakdowns in these transistors' insulating layers, prevent premature breakdowns, and ensure reliable programming. With the second transistor T1 in the circuit, programming of the OTP memory cell C1 can become more controlled and reliable, ensuring that only the changes (i.e., insulating layer breakdown in the first, third, and fourth transistors T0, T2, and T3) occur during the programming process.

The OTP memory cell C1 can enhance the success rate of programming by introducing multiple programming paths. By having multiple transistors (e.g., third and fourth transistors T2 and T3), multiple paths for potential breakdown can be created during the programming. In some embodiments, the fourth transistor T3 can be replaced with multiple PMOS transistors (see FIGS. 1C, 1D, 1G, and 1H) connected in parallel, which in turn provides multiple sites for breakdown. More breakdown sites mean a higher probability of achieving the desired programming state, allowing for an overall enhancement in the performance and reliability of the OTP memory cell C1. For example, if one path fails to break down, others might succeed, increasing overall reliability of the OTP memory cell C1. In some embodiments, one or more third transistor T2 can be configured in the OTP memory cell C1. In some embodiments, the third transistor T2 can be omitted from the OTP memory cell C1 and only the fourth transistor T3 can be configured in the OTP memory cell C1.

In some embodiments, the fourth transistor T3 can have an opposite conductivity type to the third transistor T2. For example, the third transistor T2 can be an NMOS transistor, while the fourth transistor T3 can be a PMOS transistor. This difference in conductivity types can affect how these transistors respond to voltage and how they facilitate programming. With respect to the fourth transistor T3 as the PMOS transistor, the source/drain to the high voltage word line WLP and the gate terminal to the lower voltage node (i.e., resistance node A) is for creating the conditions for the breakdown of the gate insulating layer during programming. This orientation is in line with the operation of PMOS transistors where a higher source/drain voltage relative to the gate turns the transistor on. With respect to the third transistor T2 as the NMOS transistor, the gate terminal to the high voltage word line WLP and the source/drain to the lower voltage node is for creating the conditions for the breakdown of the gate insulating layer during programming. This orientation is in line with the operation of NMOS transistors where a higher gate voltage relative to the source turns the transistor on. In some embodiments, the first and second transistors T0 and T1 are of a same conductivity type as the third transistor T2, but an opposite conductivity type to the fourth transistor T3.

Specifically, a gate terminal of the first transistor T0 is electrically coupled to the word line WLR, a gate terminal of the second transistor T1 is electrically coupled to the word line WLM, and a gate terminal of the third transistor T2 and a first source/drain terminal of the fourth transistor T3 are electrically coupled to the word line WLP. A first source/drain terminal of the first transistor T0 is electrically coupled to the bit line BL, a second source/drain terminal of the first transistor T0 is electrically coupled to a first source/drain terminal of the second transistor T1. A second source/drain terminal of the second transistor T1 is electrically coupled to a resistance node A, and a first source/drain terminal of the third transistor T2 and a gate terminal of the fourth transistor T3 are also electrically coupled to the resistance node A. A second source/drain terminal of the third transistor T2 and a second source/drain terminal of the fourth transistor T3 are floated to not have any effect on storing and reading data in the OTP memory cell C1.

In some embodiments, the OTP memory cell C1 can include more select transistors. As shown in FIG. 1B, an OTP memory cell C1′ is similar to the OTP memory cell C1 as shown in FIG. 1A. The difference between the OTP memory cell C1′ and the OTP memory cell C1 is that the OTP memory cell C1′ can include more select transistors (e.g., 1-99) compared to FIG. 1A, enabling more complex memory operations or provide access to a larger array of memory cells. Additionally, corresponding to the number of select transistors, there are additional word lines (e.g., WL_1 . . . . WL_n) in FIG. 1B. Each of these word lines is connected to the gate of the select transistors, allowing for individual or group control of rows or columns of memory cells, providing enhanced flexibility and control in memory operations. Therefore, with more select transistors and word lines, the structure in FIG. 1B can support more complex operations, such as selective programming, erasing, or reading of memory cells. In some embodiments, the OTP memory cell C1′ can omit to arrange the transistor used to relax the voltage stress as the transistor T1 as shown in FIG. 1A.

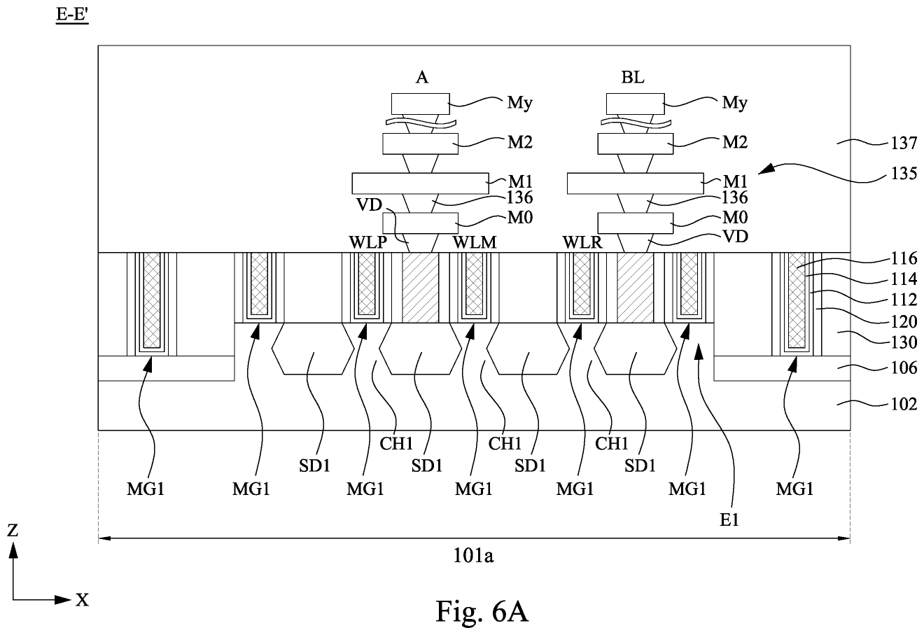

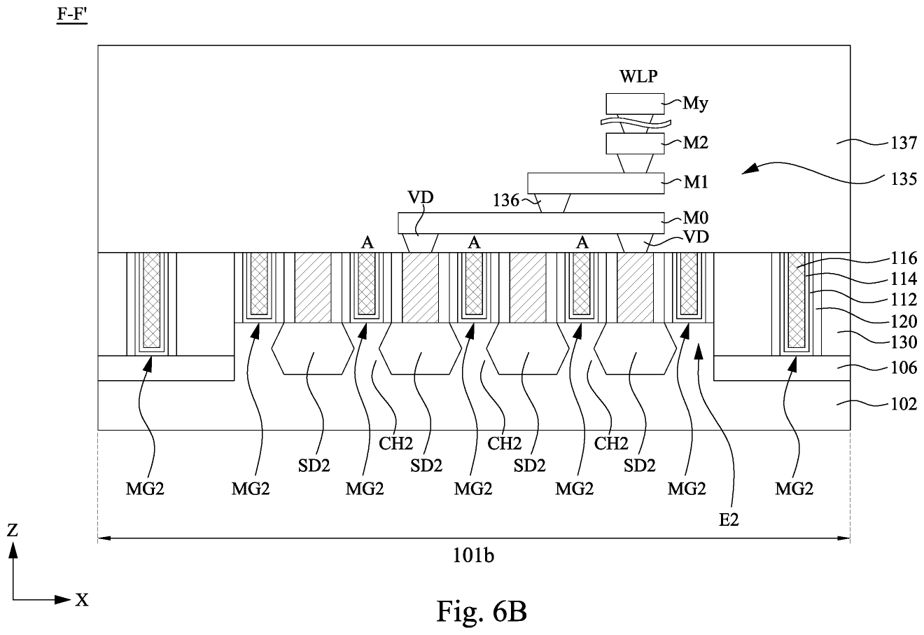

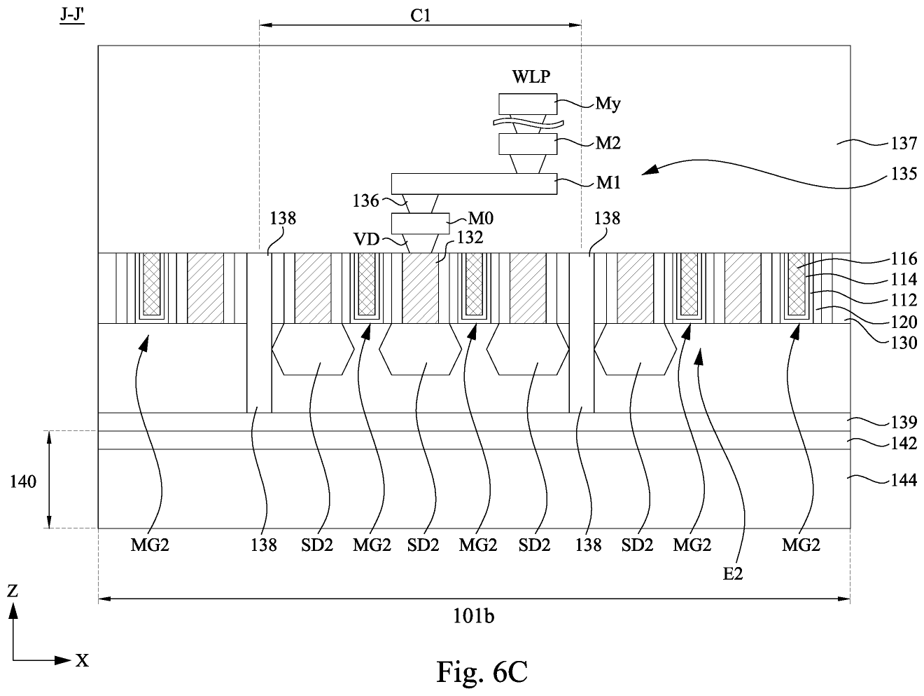

Referring back to FIG. 1A, during a programming operation, the word line WLP can be supplied with a first voltage, the world line WLR can be coupled to a second voltage having a lower level than the first voltage, and the world line WLR can be coupled to a third voltage having a level between the first and second voltages. The first voltage can be a voltage having a sufficient level to destroy an insulating layer (e.g., gate dielectric layer 112 described in FIGS. 6A and 6B) included in a gate structure (e.g., metal gate structures MG1 and MG2 described in FIGS. 6A and 6B) of the first transistor T0, and the second and third voltages can be voltages having sufficient levels to turn on the first and second transistors T0 and T1. In some embodiments, the first voltage may be higher than about 1.2V, and the second voltage may be about 0.5V-10V, which is sufficiently high to turn on the first and second transistors T0 and T1. The bit line BL can be coupled to a fourth voltage (e.g., ground voltage) lower than the first, second, and third voltages. In some embodiments, the ground voltage can be regarded as having a voltage level of about 0V. By way of example and not limitation, during the programming operation, the word line WLP may be supplied with 4V, the word line WLM may be supplied with 1.2V, and the word line WLR may be supplied with 0.75V.

Since the gates of the first and second transistors T0 and T1 can be supplied with second and third voltages that are sufficiently high to turn on the first and second transistors T0 and T1, the gates of the first and second transistors T0 and T1 are turned on, and thus the resistance node A is coupled to the fourth voltage (e.g., ground voltage). The gate of the third transistor T2 and the first source/drain terminal of the fourth transistor T3 are coupled to the first voltage with high level. With respect to the third transistor T2, due to a voltage difference between a voltage level (e.g., first voltage) supplied to the gate of the third transistor T2 and another voltage level (e.g., fourth voltage) supplied to the first source/drain terminal of the third transistor T2, the insulating layer of the third transistor T2 can be destroyed, i.e., broken down. Similarly, with respect to the fourth transistor T3, due to a voltage difference between a voltage level (e.g., first voltage) supplied to the first source/drain terminal of the fourth transistor T3 and another voltage level (e.g., fourth voltage) supplied to the gate terminal of the fourth transistor T3, the insulating layer of the fourth transistor T3 can be destroyed, i.e., broken down. When at least one of the insulating layers is destroyed, a current path is created between the word line WLP and the resistance node A. The resulting circuit can be regarded as having a resistance in the current path. Accordingly, is this condition, the OTP memory cell C1 can be referred to as “programmed” after the programming operation, because the insulating layer of at least one of the third and fourth transistors T2 and T3 is broken down.

In some embodiments, the fourth voltage applied to the bit line BLI can have a higher voltage level than the ground voltage (e.g., about 0V), such as about 1.2V. In some embodiments, the fourth voltage applied to the bit line BLI can substantially have the same value as the second and/or third voltages. Therefore, a voltage difference between the gate terminal of the first transistor T0 and the first source/drain terminal of the first transistor T0 may be about zero, and a voltage difference between the gate terminal of the second transistor T1 and the first source/drain terminal of the second transistor T1 may be about zero, such that the first and second transistors T0 and T1 are turned off, which in turn allows for floating the second source/drain terminal of the second transistor T1 connected to the third and fourth transistors T2 and T3. Even though the first voltage with high level is applied to the third and fourth transistors T2 and T3 through the word line WLP, an electric field will not be applied to the insulating layers of the third and fourth transistors T2 and T3 because the first source/drain terminal of the third transistor T2 and the gate terminal of the fourth transistor T3 connected to the first and second transistors T0 and T1 is floated. In this way, the insulating layers of the third and fourth transistors T2 and T3 may not be broken down during the programming operation, the third and fourth transistors T2 and T3 remain its' original function after the programming operation. Accordingly, in this condition, the OTP memory cell C1 can be referred to as “un-programmed” after the programming operation, because the insulating layers of third and fourth transistors T2 and T3 are not broken down.

During a read operation, the word line WLP can be supplied with a fifth voltage, and the word lines WLR and WLM can be coupled to sixth and seventh voltages, in which the seventh voltage has a voltage level between the fifth and sixth voltages. The bit line BL can be pre-charged with a ground voltage level. The sixth and seventh voltages can be sufficiently high to turn on the first and second transistor T0 and T1. In the condition 1 where the at least one of the insulating layers included in the gate structures of the third and fourth transistors T2 and T3 is destroyed (i.e., breakdown state), the voltage of the bit line BL may increase, which in turn increases a current path between the gate terminal of the third transistor T2 and the bit line BL and/or increases a current path between the first source/drain terminal of the fourth transistor T3 and the bit line BL. On the other hand, in the condition where the insulating layers included in the gate structures of third and fourth transistors T2 and T3 are not destroyed, the voltage level of bit line BL does not rise and therefore retains the pre-charged voltage level (i.e., ground voltage level), and thus there is no current path between the gate terminal of the third transistor T2 and the bit line BL and between the first source/drain terminal of the fourth transistor T3 and the bit line BL. Data can be read depending on whether there is current on the bit line BL. For instance, in the condition where the at least one of the insulating layers included in the gate structures of the third and fourth transistors T2 and T3 is destroyed, if the voltage or the current of the bit line BL increases because of the breakdown of the insulating layer of the third transistor T2/fourth transistor T3, data ‘1’ can be determined. On the other hand, if the voltage or the current of the bit line BL does not rise, data ‘0’ can be determined. That is, if at least one of the insulating layers breaks down, the bit line BL may have a logic level of ‘1’; if the insulating layers do not break down, the bit line BL may have a logic level of ‘0’. By way of example and not limitation, during the programming operation, the word line WLP may be supplied with 1.3V, the word line WLM may be supplied with 1.2V, and the word line WLR may be supplied with 0.75V.

Reference is made to FIGS. 1C, 1E, and 1F. FIG. 1C is a top view of the OTP memory cell C1 corresponding to the circuit diagram of the memory device 100 as shown in FIG. 1A in accordance with some embodiments of the present disclosure. FIGS. 1E and 1F illustrate cross-sectional views taken along line E-E′ and line F-F′ as shown in FIG. 1C. In FIG. 1C, the OTP memory cell C1 can be separated into two distinct regions (e.g., first and second conductivity type device regions 101a and 101b) based on their conductivity types and situated in a same bank B0.

Specifically, the first conductivity type device region 101a can include NMOS transistors, which utilize n-type material for the channel and require a positive gate voltage relative to the source to conduct. The transistors T0, T1, and T2 within the first conductivity type device region 101a can be NMOS transistors, and can be used in the operation of the OTP memory cell, such as switching, voltage stress relaxation, and control of programming paths. The second conductivity type device region 101b can include PMOS transistors, which utilize p-type material for the channel and typically need a negative gate voltage relative to the source to conduct. Anti-fuse transistors T31, T32, T33 in the second conductivity type device region 101b can be PMOS transistors and are connected in parallel. These parallel-connected PMOS transistors can serve as an equivalent circuit to the third transistor T3 in FIG. 1A. Their parallel connection can enhance the probability of successful programming by providing multiple potential breakdown sites. Additionally, in the OTP memory cell C1, an equal or proportionate number of PMOS and NMOS transistors can be utilized for maintaining uniform electrical characteristics across the OTP memory cell C1. That is, the balanced ratio of PMOS and NMOS transistors in the OTP memory cell C1 can optimize the manufacturing process and also contribute to the memory cell's stable and efficient performance.

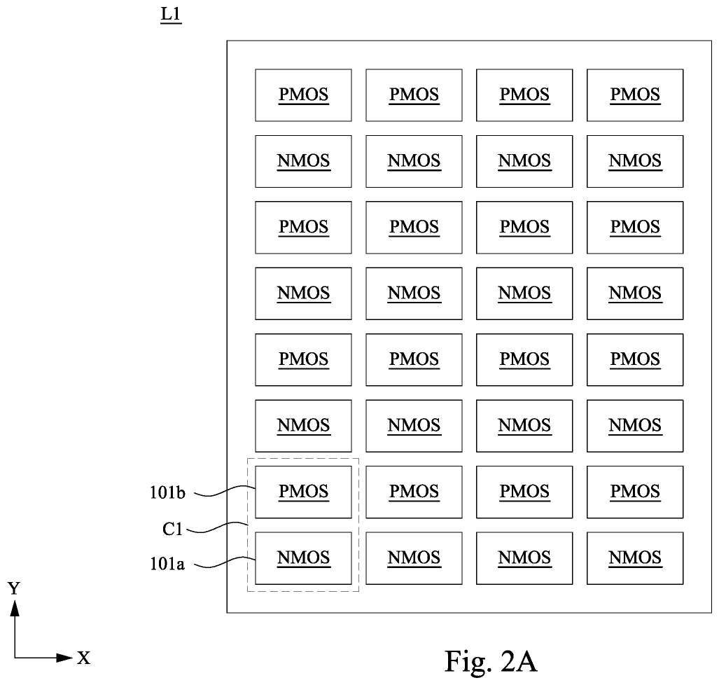

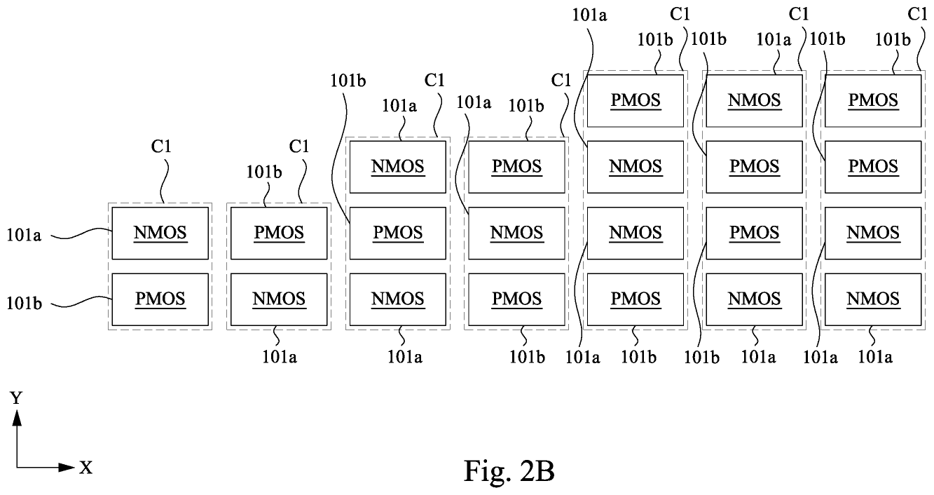

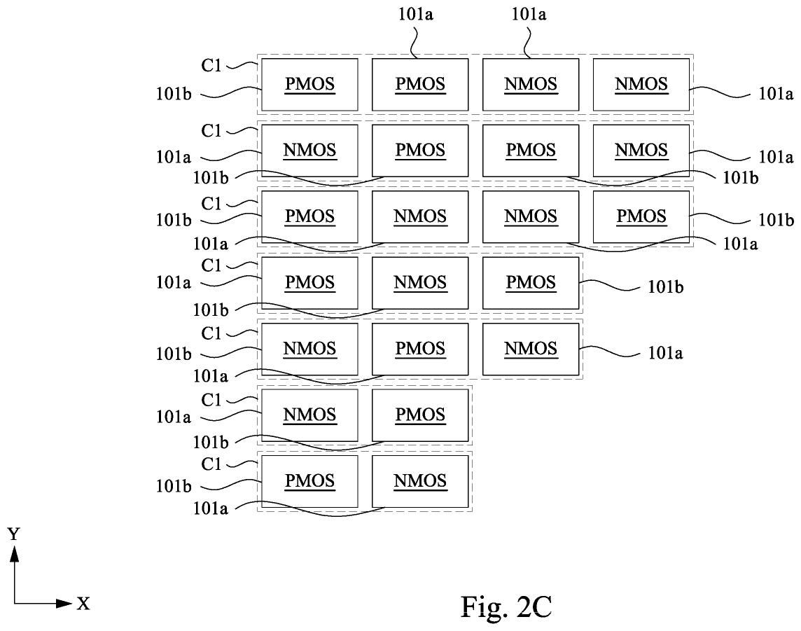

Furthermore, the balanced distribution of NMOS and PMOS transistors in the OTP memory cell array L1 can enhance overall process quality. In the OTP memory cells C1, as depicted in the layouts of FIGS. 2A-2C, balancing the number of PMOS and NMOS transistors across the array L1. This balance is achieved through the inclusion of first and second conductivity type device regions 101a and 101b in the memory cells C1. The OTP memory cells C1 can incorporate both NMOS and PMOS transistors. In the array layout, the number of NMOS transistors present in the first conductivity type device region 101a can be made equal to or close to the number of PMOS transistors in the second conductivity type device region 101b, ensuring an even distribution of different types of transistors across the array L1. FIGS. 2A-2C illustrate various arrangements of the OTP memory cells C1 within the memory device 100. These arrangements can maintain a balance in the transistor types. By evenly distributing NMOS and PMOS transistors, the fabrication process becomes more uniform. This uniformity is beneficial for achieving consistent electrical characteristics and performance across the entire memory array L1. In some embodiments, the OTP memory cell array L1 can incorporate different regions, such as dummy cell regions, OD-spacing effect (OSE) regions where three-terminal floating MOS situated on, or pick up cell regions, in the placement of memory cells C1.

FIGS. 2A-2C show how the first and second conductivity type device regions 101a and 101b in the OTP memory cells C1 can be arranged in various configurations within the array L1 to achieve a balanced PMOS/NMOS ratio. In FIG. 2B, the first and second conductivity type device regions 101a and 101b in the OTP memory cells C1 can be arranged vertically (in the Y direction), and in FIG. 2C, the first and second conductivity type device regions 101a and 101b in the OTP memory cells C1 can be arranged horizontal (in the X direction). The number of the first conductivity type device regions 101a can either match or differ from the number of the second conductivity type device regions 101a.

As shown in FIGS. 2B and 2C, the positions of the first and second conductivity type device regions 101a and 101b can be flipped or interchanged. In some embodiments, different sandwich configurations can build a balanced transistor environment. For example, two first conductivity type device regions 101a can sandwich a second conductivity type device region 101b. Alternatively, two second conductivity type device regions 101b can sandwich a first conductivity type device region 101a. Another configuration can have two second conductivity type device regions 101b sandwiching two adjacent first conductivity type device regions 101a, creating a pattern with equal PMOS and NMOS regions. Alternatively, two first conductivity type device regions 101a can sandwich two adjacent 101b regions, maintaining a balance of PMOS and NMOS transistors. Another configuration can have two adjacent first conductivity type regions 101a next to two adjacent second conductivity type regions 101b.

Referring back to FIGS. 1C, 1E, and 1F, the memory device 100 may include a substrate 102 (see FIGS. 1E and 1F), the transistors T0, T1, and T2 can be formed within the first conductivity type device region 101a over the substrate 102, and the transistors T31, T32, T33 can be formed within the second conductivity type device region 101b over the substrate 102. In some embodiments, the transistors T31, T32, T33 can have an opposite conductivity type to the transistors T0, T1, and T2. For example, the transistors T31, T32, T33 can be PMOS transistors, while the transistors T0, T1, and T2 can be NMOS transistors. Specifically, each of the transistors T0, T1, and T2 can include a channel region CH1 (see FIG. 1E), source/drain structures SD1 (see FIG. 1E) at opposite sides of the channel region CH1, and a metal gate structure MG1 (see FIG. 1E) around the channel region CH1. Each of the transistors T31, T32, T33 can include a channel region CH2 (see FIG. 1F), source/drain structures SD2 (see FIG. 1F) at opposite sides of the channel region CH2, and a metal gate structure MG2 (see FIG. 1F) around the channel region CH2.

The memory device 100 may include a plurality of active regions E1 and E2 over the substrate 102. The active region E1 can be formed within the first conductivity type device region 101a, and the active region E2 can be formed within the second conductivity type device region 101b. In some embodiments, the active region E1/E2 can be interchangeably referred to as an oxide definition (OD). In some embodiments, the active regions E1 and E2 can be fin structures. The source/drain structures SD1 (see FIG. 1E) are formed in the active region E1, and the source/drain structures SD2 (see FIG. 1F) are formed in the active region E2. Portions of the active region E1 (i.e., fin-like structure) between the corresponding source/drain regions SD1 can serve as the channel regions CH1 (see FIG. 1E), and portions of the active region E2 (i.e., fin-like structure) between the corresponding source/drain regions SD2 can serve as the channel regions CH2 (see FIG. 1F). In some embodiments, the source/drain structures SD1 can be doped with a first impurity (or first dopant), and the source/drain structures SD2 can be doped with a second impurity (or second dopant) having an opposite conductivity type to the first impurity. By way of example and not limitation, the source/drain structures SD1 can be doped with an n-type impurity (e.g., phosphorous), and the source/drain structures SD2 can be doped with a p-type impurity (e.g., boron). In some embodiments, the source/drain structure SD1/SD2 can be interchangeably referred to as a source/drain structure region, a source/drain pattern, or an epitaxial structure. In some embodiments, the channel region CH1/CH2 can be interchangeably referred to as a channel pattern, a channel layer, or a nanopedestal structure.

Metal gate structures MG1 (see FIG. 1E) each can be formed between corresponding two of the source/drain structures SD1, and metal gate structures MG2 (see FIG. 1F) can be formed between corresponding two of the source/drain structures SD2. In some embodiments, the metal gate structure MG1/MG2 can be interchangeably referred to as a gate, metal gate, a metal gate strip, a metal gate layer, a metal gate pattern, or a poly (PO) structure. Source/drain contacts 132 can be formed over the source/drain regions SD1 and SD2. In some embodiments, the source/drain contacts 132 can be interchangeably referred to as a metal contact or a metal-like defined region (MD).

A dielectric region 134 (see FIG. 1C) can be formed to laterally extend along a direction perpendicular to lengthwise directions of the metal gate structures MG1 and MG2, and situated between the source/drain structures SD1 (see FIG. 1E) and the source/drain structures SD2 (see FIG. 1F) to separate the source/drain contacts SD1 and SD2, and between the metal gate structures MG1 and the metal gate structures MG2 to separate the metal gate structures MG1 and MG2. In some embodiments, the dielectric region 134 can be a metal-like defined region (MD)-cut structure for forming the source/drain contact 132, and the MD-cut structure can be formed by a cut metal-like defined region (CMD) process. In some embodiments, the dielectric region 134 can be interchangeably referred to as a dielectric structure.

An interconnect structure 135 (see FIGS. 1E and 1F) can be formed over the metal gate structures MG1 and MG2. Specifically, the interconnect structure 135 can be formed to have source/drain vias VD (see FIGS. 1E and 1F) connecting to the source/drain contacts 132. The interconnect structure 135 may further include, for example, a plurality of metallization layers M0, M1, M2 . . . . My (see FIGS. 1E and 1F), with a plurality of layers of metallization vias (or interconnects) 136 (see FIGS. 1E and 1F), connecting adjacent two of the metallization layers M0, M1, M2 . . . . My, and the source/drain vias VD are connected to the corresponding metallization layers M0, where y represents the number of metal levels, which can be determined based on the application. Throughout the description, the notations of metallization layers may be followed by the metal layer levels they are in. For example, the metallization layers disposed at the M0 level over the substrate 102 may include the metallization layers M0, the metallization layers disposed at the M1 level over the metallization layers M0 may include the metallization layers M1, the metallization layers disposed at the M2 level over the metallization layers M1 may include the metallization layers M2. In some embodiments, the metallization layers disposed at a level may have lengthwise directions perpendicular to the metallization layers disposed at a next level. In some embodiments, the metallization layers M0, M1, M2 . . . . My can be interchangeably referred to as metal layers, metal lines, or line patterns, and the metallization vias 136 can be interchangeably referred to as vias, metal vias, or via patterns.

In FIG. 1E, the metal gate structure MG1 of the transistor T0 is electrically coupled to the reading word line (e.g., word line WLR shown in FIG. 1A), the metal gate structure MG1 of the second transistor T1 is electrically coupled to another word line (see word line WLM shown in FIG. 1A), and the metal gate structure MG1 of the third transistor T2 is electrically coupled to the programming word line (see word line WLP shown in FIG. 1A). The metal gate structure MG1 of the transistor T2 is for creating the conditions for the breakdown of the gate dielectric layer (e.g., gate dielectric layer 112 as shown in FIG. 6A) thereof during programming.

One of the source/drain structures SD1 of the transistor T0 can be electrically connected to the bit line through a circuit route R1 in the interconnect structure 135, in which the circuit route R1 can include corresponding ones of the source/drain vias VD, the metallization layers M0, M1, M2 . . . . My, and the metallization vias 136, and the topmost metallization layer My in the circuit route R1 can act as the bit line. The first transistor T0 can share another one of the source/drain structures SD1 thereof with the second transistor T1.

The transistor T1 can share a corresponding one of the source/drain structures SD1 thereof opposite to the first transistor T0 with the transistor T2. The sharing one of the source/drain structures SD1 of the transistors T1 and T2 can be electrically coupled to the resistance node (e.g., resistance node A shown in FIG. 1A). Specifically, the sharing one of the source/drain structures SD1 of the transistors T1 and T2 can be electrically connected to the resistance node through a circuit route R2 in the interconnect structure 135, in which the circuit route R2 can include corresponding ones of the source/drain vias VD, the metallization layers M0, M1, M2 . . . . My, and the metallization vias 136, and the topmost metallization layer My in the circuit route R2 can act as the resistance node. The transistor T2 can have another one of the source/drain structures SD1 opposite to transistor T1 to be floated to not have any effect on storing and reading data in the OTP memory cell C1.

In FIG. 1F, the metal gate structures MG2 of the transistors T31, T32, T33 can be electrically connected to the resistance node (e.g., resistance node A shown in FIG. 1A). The metal gate structure MG2 of the transistors T31, T32, T33 are for creating the conditions for the breakdown of the gate dielectric layer (e.g., gate dielectric layer 112 as shown in FIG. 6B) thereof during programming. The transistors T31, T32, T33 can provide multiple sites for breakdown. By having multiple transistors T2, T31, T32, and T33, multiple paths for potential breakdown can be created during the programming. Therefore, the OTP memory cell C1 can enhance the success rate of programming by introducing multiple programming paths.

Specifically, the transistors T31, T32, T33 are connected in parallel. The transistors T31 can share one of the source/drain structures SD2 with the transistors T32, and the transistors T32 can share another one of the source/drain structures SD2 with the transistors T33. The sharing one of the source/drain structures SD2 of the transistors T32 and T33 can be electrically connected to another one of the source/drain structures SD2 of the transistors T31 opposite to the transistors T32, through the corresponding source/drain vias VD and metallization layer M0, and further electrically connected to the programming word line (e.g., word line WLP shown in FIG. 1A). In other words, the corresponding ones of the source/drain structures SD2 can be electrically connected to the programming word line through a circuit route R3 in the interconnect structure 135, in which the circuit route R3 can include corresponding ones of the source/drain vias VD, the metallization layers M0, M1, M2 . . . . My, and the metallization vias 136, and the topmost metallization layer My in the circuit route R3 can act as the programming word line. The transistor T33 can have another one of the source/drain structures SD2 opposite to transistor T32 to be floated to not have any effect on storing and reading data in the OTP memory cell C1. The sharing one of the source/drain structures SD2 of the transistors T31 and T32 can be floated to not have any effect on storing and reading data in the OTP memory cell C1.

In the OTP memory cell C1, as described in the context of FIGS. 1C, 1E, and 1F, the order of connection for the source/drain structures SD2 of transistors T31, T32, and T33 can be adjusted, particularly in relation to the programming word line WLP and floating (PF) states, and this adjustment is for the operational effectiveness of the memory cell.

Reference is made to FIG. 1D. FIG. 1D is a top view of the memory device 100 in accordance with some embodiments. FIGS. 1C and 1D both reflect the schematic circuit diagram shown in FIGS. 1A and 1B that includes 3 NMOS transistors and 1 set of PMOS transistors (e.g., including at least one PMOS transistor). Specifically, the memory device 100 shown in FIG. 1C represents a simplified layout pattern of the OTP memory cell C1. The memory device 100 shown in FIG. 1D represents a more detailed representation of the OTP memory cell C1, including additional structures not detailed in FIG. 1C. The memory device 100 shown in FIG. 1D can include additional metal gate structures MG1 and MG2 and source/drain contacts 132 on both opposite sides of the OTP memory cell C1. These additional structures can be used to space out other components adjacent to the OTP memory cell C1. Therefore, a cell width W1 of the OTP memory cell C1 in FIG. 1D can be defined as being about greater than or equal to 7 contact poly pitch (CPP, i.e., gate pitch), indicating the size and spacing considerations in the memory cell design. The memory device 100a can also include cut polysilicon (CPO) structures 133, which can be used to truncate and separate adjacent metal gate structures MG1 and MG2. These structures is for isolating individual transistors or transistor groups within the OPT memory cell C1. The memory device 100 further illustrates poly on oxide definition (PODE) regions 131, which represent areas where the edges of active regions E1 and E2 overlap with metal gate structures MG1 and MG2. Additionally, FIG. 1D illustrates that the dielectric regions 134 can be further situated at the cell boundary B1 of the OTP memory cell C1.

Reference is made to FIGS. 1G-1J. FIGS. 1G and 1H are top views of a memory device 100a in accordance with some embodiments and represents different layout patterns for the OTP memory cell C1 than the memory device 100 shown in FIGS. 1C-1F. The memory device 100a also can reflect the schematic circuit diagram shown in FIGS. 1A and 1B containing 3 NMOS transistors and 1 set of PMOS transistors (e.g., including at least one PMOS transistor). The memory device 100a shown in FIG. 1G represents a simplified layout pattern of the OTP memory cell C1. The memory device 100a shown in FIG. 1H represents a more detailed representation of the OTP memory cell C1, including additional structures not detailed in FIG. 1H. FIG. 1I a schematic diagram of a semiconductor structure having a connected poly on oxide definition (OD) edge (CPODE) structure 138 to separate two different program devices in accordance with some embodiments. FIG. 1J illustrates a cross-sectional view taken along line J-J′ as shown in FIG. 1G. While FIGS. 1G-1J show an embodiment of the memory device 100a with different layout profiles than the memory device 100 in FIGS. 1C-1F, the present disclosure may repeat reference numerals and/or letters in the various examples. This repetition is for the purpose of simplicity and clarity and does not in itself dictate a relationship between the various embodiments and/or configurations discussed.

The memory device 100a can the include CPODE structure 138 situated at the cell boundary B1a (see FIG. 1H), which in turn omits PODE regions 131 as shown in FIG. 1D. These additional structures can be used to separate two different program devices into independent substrates and block channels, such that the substrate 102 can be isolated horizontally by the CPODE structure 138. Therefore, a cell width W1a (see FIG. 1H) of the OTP memory cell C1 in FIG. 1H can be defined as being about greater than or equal to 4 contact poly pitch. In some embodiments, the cell width W1a (see FIG. 1H) can be narrower than the cell width W1 (see FIG. 1D). Additionally, the memory device 100a can include an isolation structure 106 (see FIG. 1I) laterally surrounding the active regions E1 and E2 (see FIGS. 1G and 1H) over the substrate 102 and an additional insulation layer 139 (see FIG. 1I) underlying the CPODE structures 138, the isolation structure 106, and the substrate 102, such that the active regions E1 and E2 where the transistors are positioned thereon can be enclosed by the insulation layer 139, the CPODE structures 138, and the isolation structure 106. The substrate 102 can be vertically isolated using the isolation structure 106. By isolating the substrate vertically, the isolation structure 106 can help to prevent interference and crosstalk between different elements of the device, enhancing its overall reliability and performance. In the super-power-rail (SPR) process, the substrate 102 may undergoes additional isolation using the CPODE structure 138 implemented in MOSFETs. The CPODE structure 138 can stop substrate leakage, maintaining the device's performance and contributing to achieve high performance in the SPR process. A back-side interconnect structure 140 (see FIG. 6C) can formed over the back-side insulation layer 139.

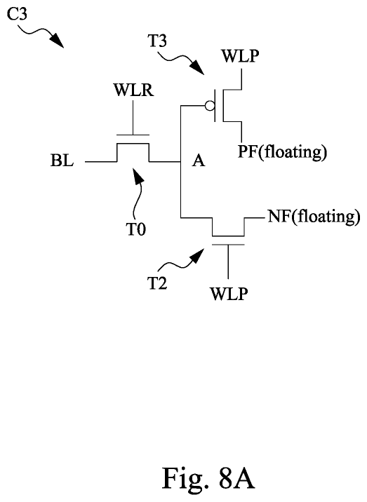

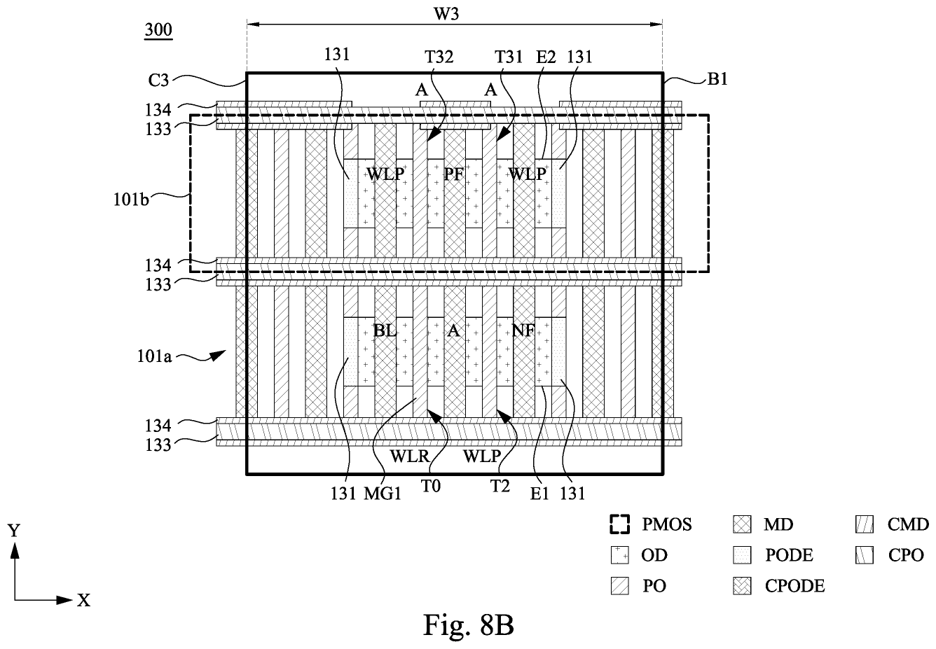

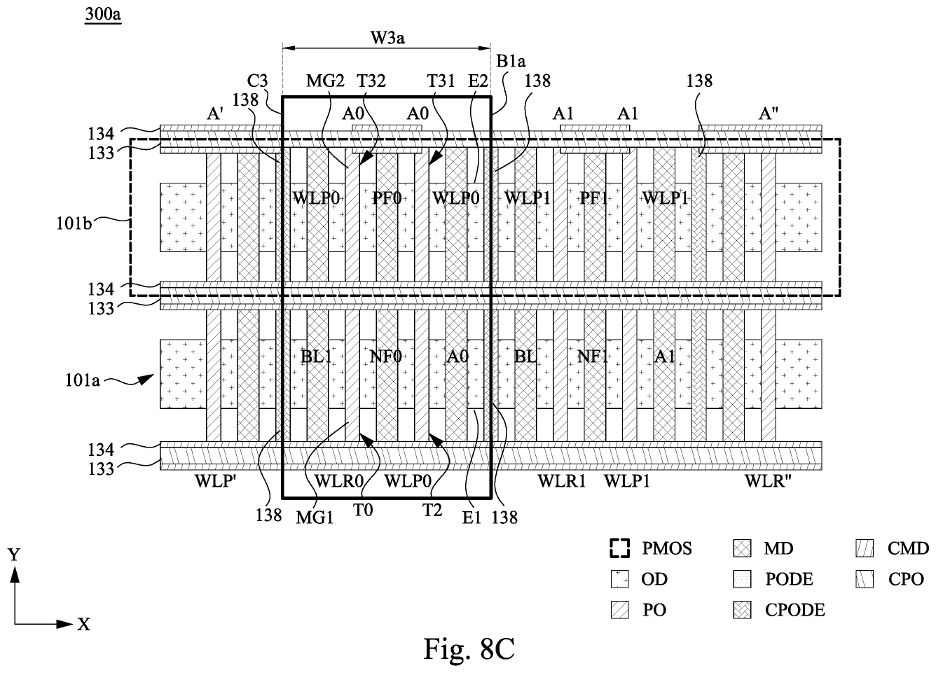

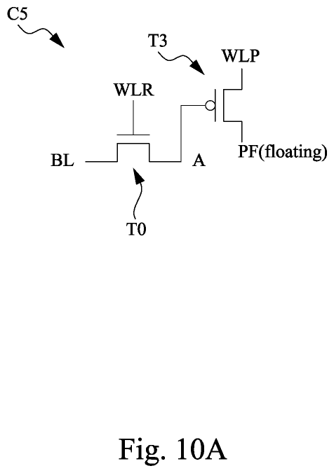

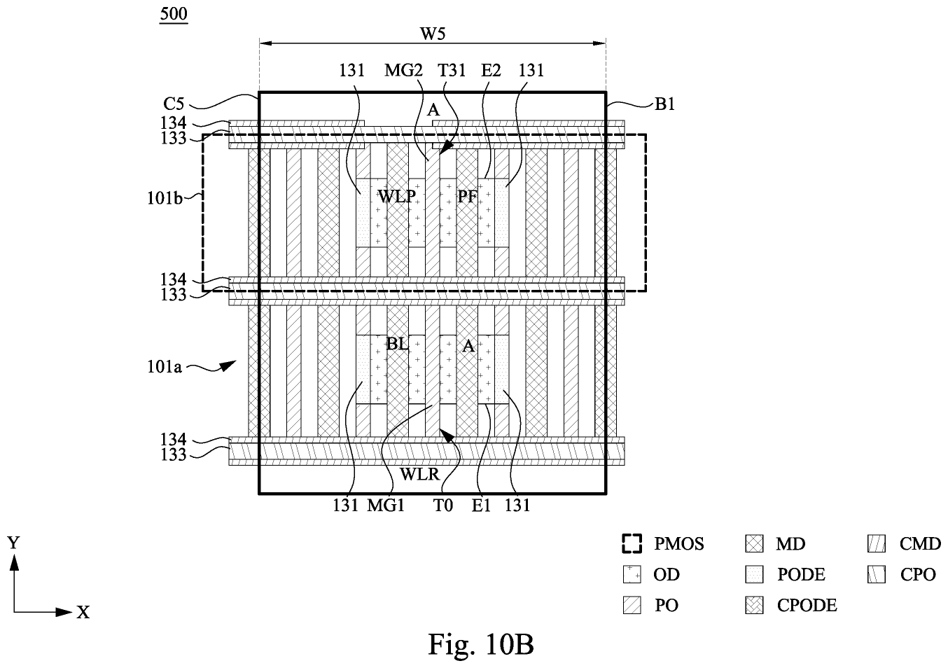

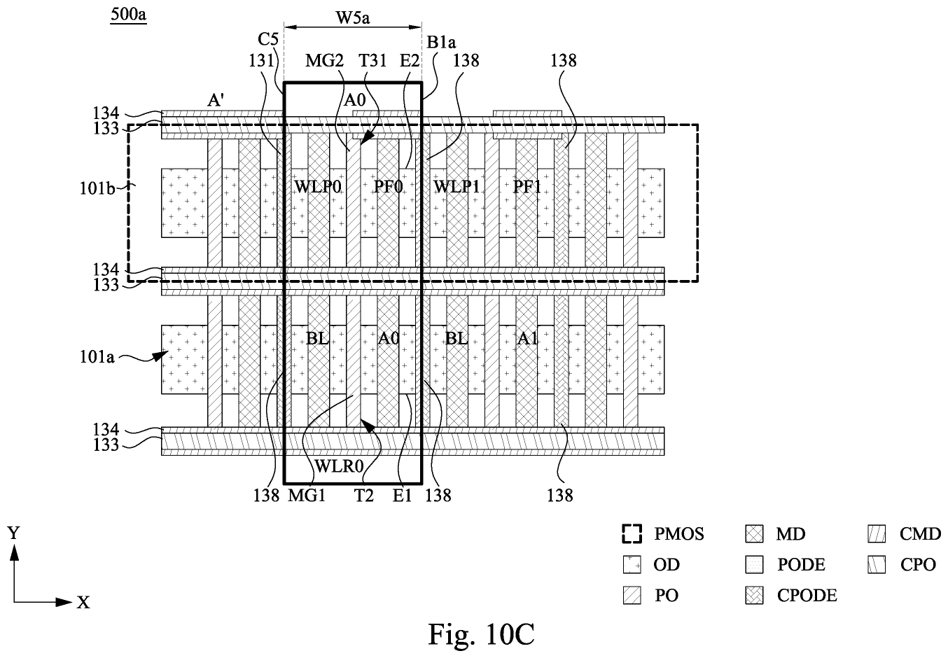

In some embodiments, the OTP memory cells in memory device 100 can be configured to a single side configuration or a dual side configuration. In the single side configuration of memory device 100, individual OTP memory cells C1 can operate with their distinct bit lines, and this architecture can be characterized by two variations, in which a first one is without CPODE structure 138 and a second one is with CPODE structure 138. The layout can exclude the CPODE structure 138, thereby impacting the transistor arrangement within the memory cells. In some embodiments (see FIG. 10B), memory cells can include the transistors T0 and T3, while omitting the transistors T1 and T2. Another variation (see FIG. 8B) can include the transistors T0, T2, and T3, while omitting the transistor T1. In addition, the layout can incorporate the CPODE structure 138. In some embodiments (see FIG. 10C), memory cells can include the transistors T0 and T3, while omitting the transistors T1 and T2. Another variation (see FIG. 8C) can include the transistors T0, T2, and T3, while omitting the transistor T1. In some embodiments, the CPODE structure 138 can be interchangeably referred to as a dielectric-base gate, a dielectric strip, or a dielectric line.

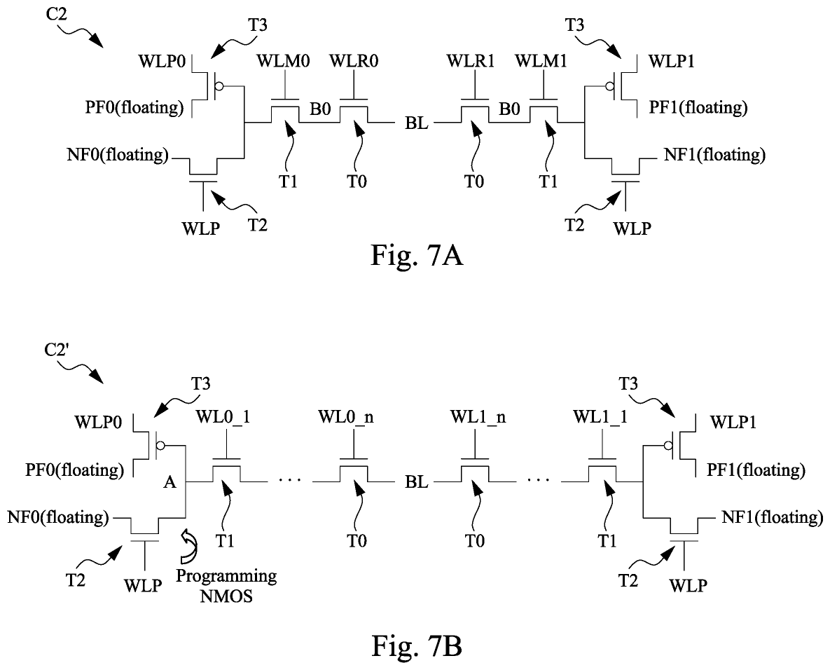

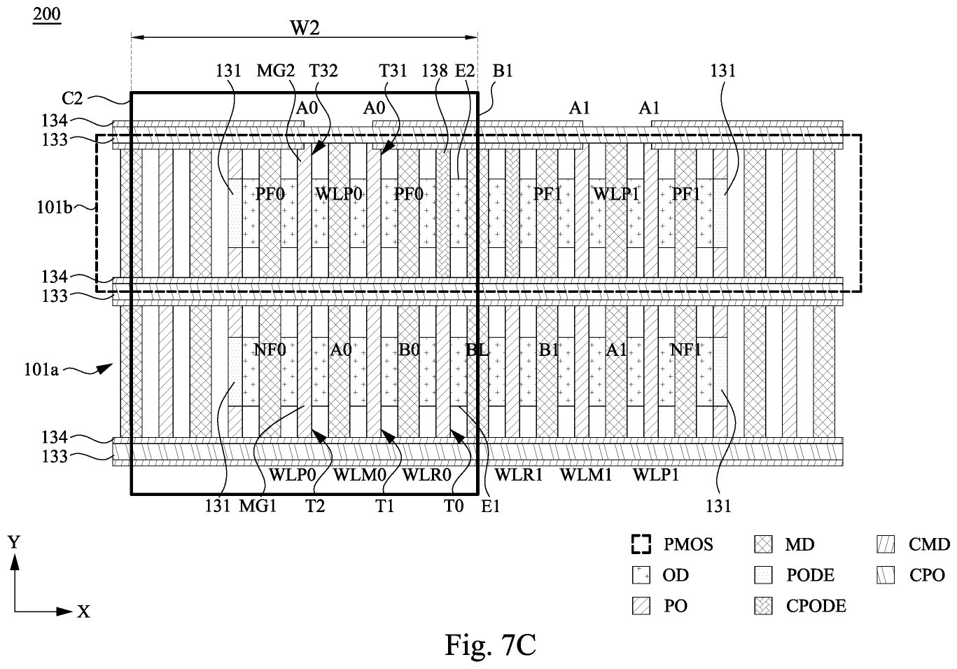

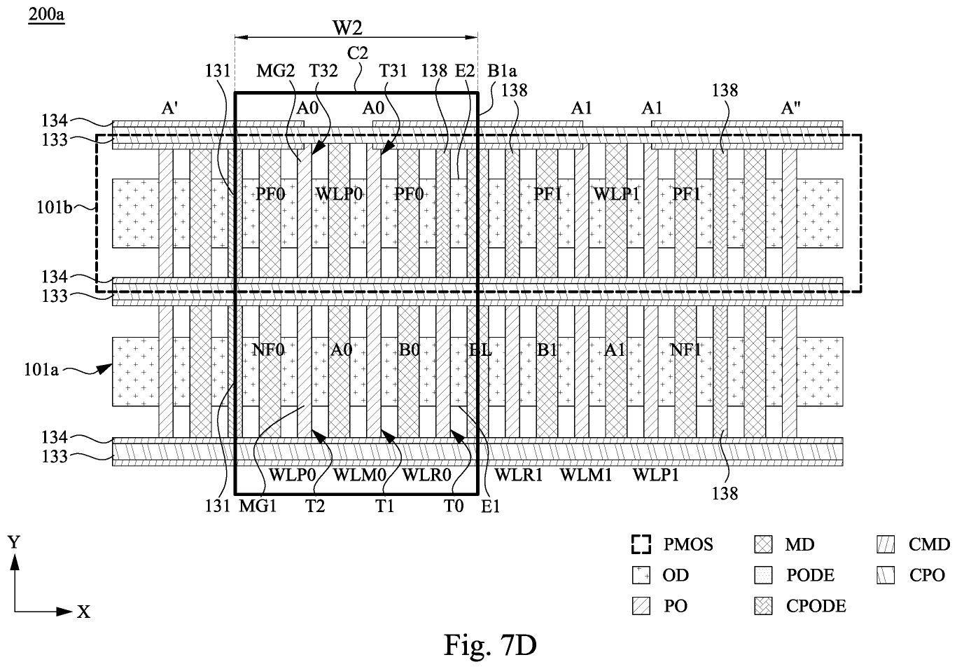

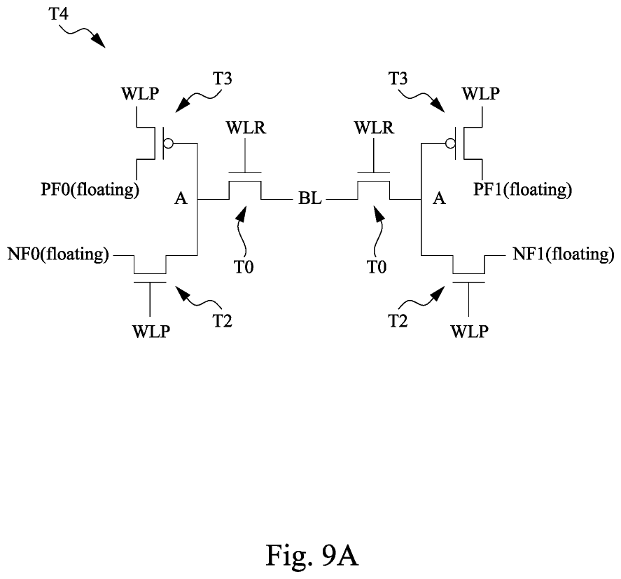

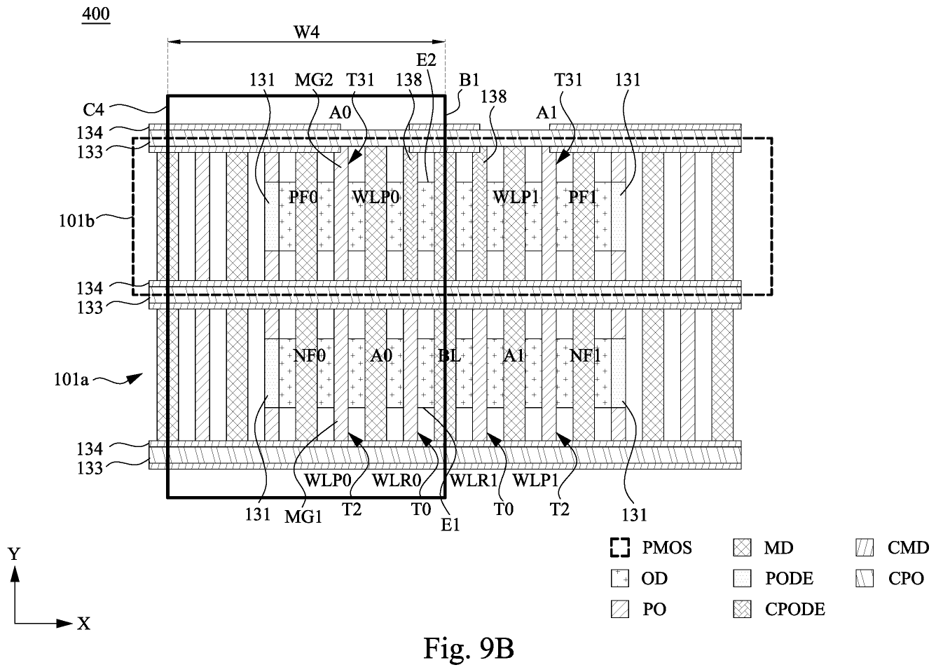

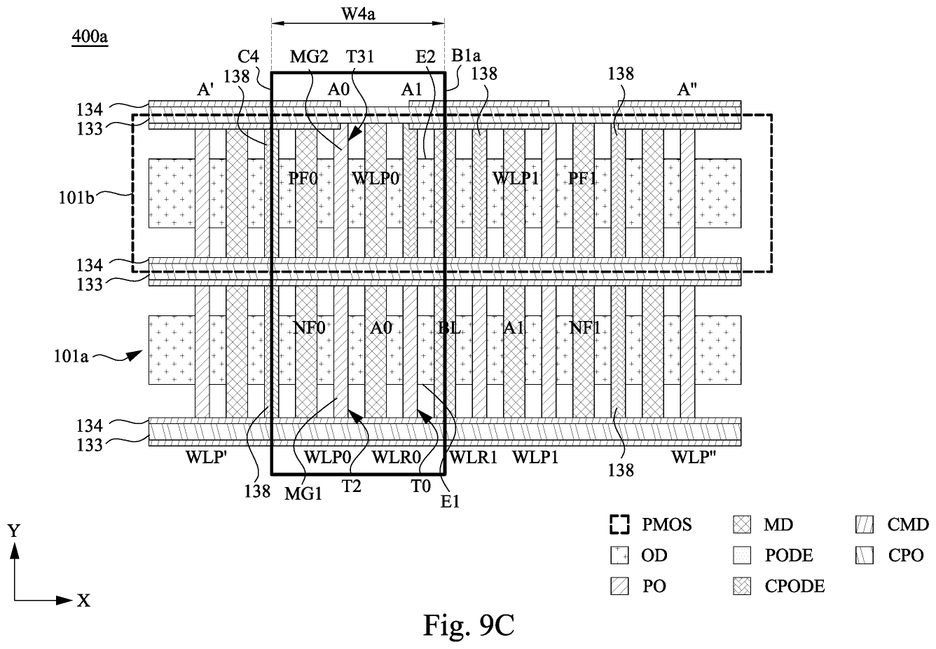

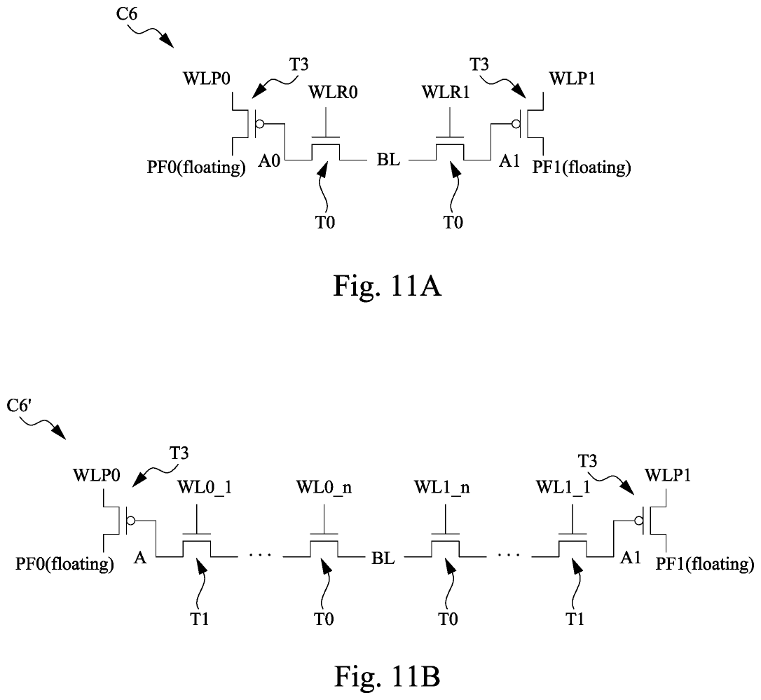

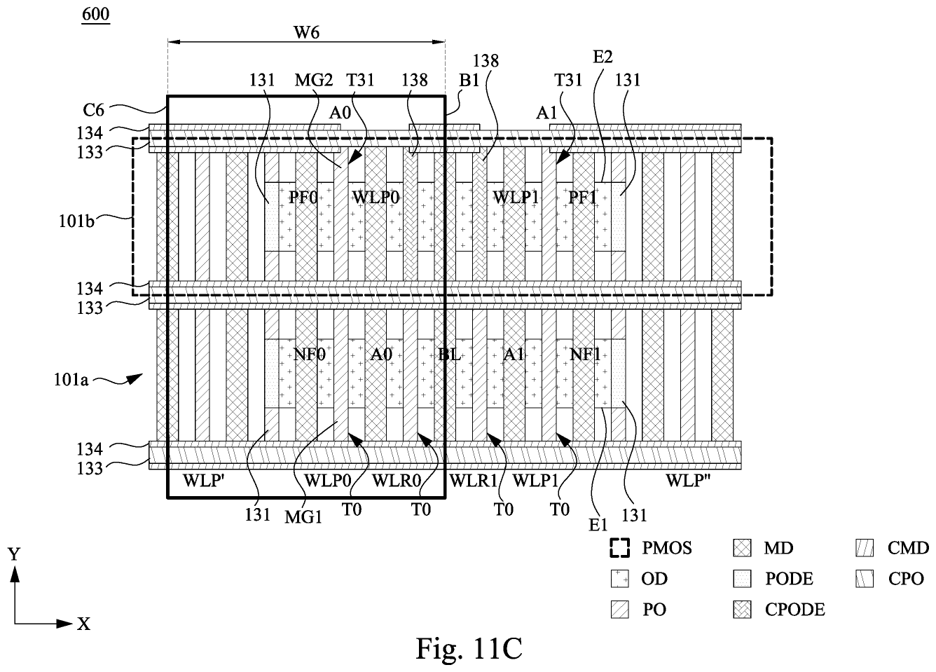

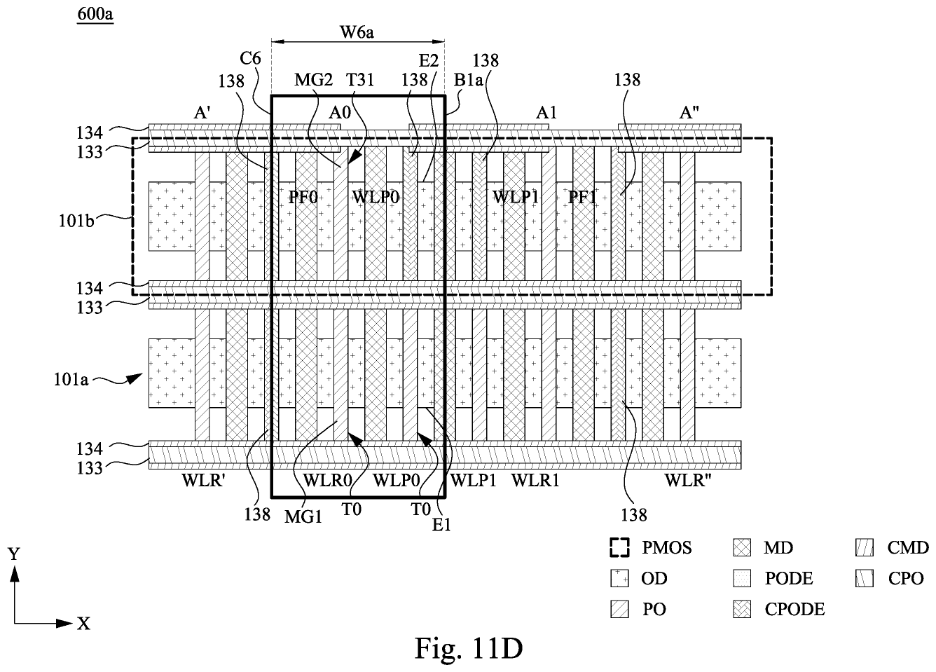

In the dual side configuration, the adjacent OTP memory cells C1 can share the same bit line, which in turn optimizes space utilization within the memory array, and this architecture can be characterized by two variations, in which a first one is without CPODE Structure 138 and a second one is with CPODE structure 138. The layout can exclude the CPODE structure 138, thereby impacting the transistor arrangement within the memory cells. In some embodiments (see FIG. 11C), memory cells can include the transistors T0 and T3, while omitting the transistors T1 and T2. Another variation (see FIG. 9B) can include the transistors T0, T2, and T3, while omitting the transistor T1. Additionally, the configurations can be with all four transistors T0, T1, T2, and T3 (see FIG. 7C). In addition, the layout can incorporate the CPODE structure 138. In some embodiments (see FIG. 11D), memory cells can include the transistors T0 and T3, while omitting the transistors T1 and T2. Another variation (see FIG. 9C) can include the transistors T0, T2, and T3, while omitting the transistor T1. Additionally, the configurations can be with all four transistors T0, T1, T2, and T3 (see FIG. 7D).

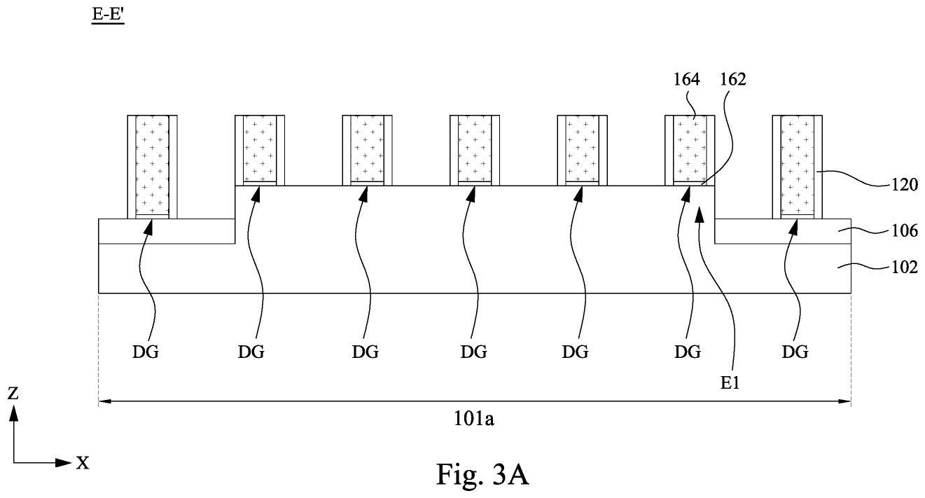

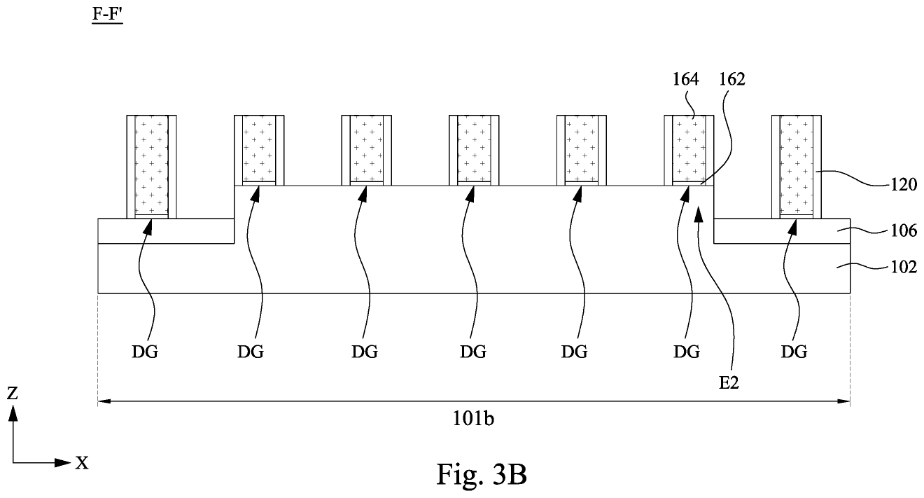

Reference is made to FIGS. 3A-5B, 6A, and 6B. FIGS. 3A-5B, 6A, and 6B illustrate schematic views of intermediate stages in the manufacturing of the memory device 100 in accordance with some embodiments. FIGS. 3A, 4A, 5A, and 6A illustrate cross-sectional views obtained from reference cross-section E-E′ in FIG. 1C. FIGS. 3B, 4B, 5B, and 6B illustrate cross-sectional views obtained from reference cross-section F-F′ in FIG. 1C. It is understood that additional operations can be provided before, during, and after the processes shown by FIGS. 3A-5B, 6A, and 6B, and some of the operations described below can be replaced or eliminated, for additional embodiments of the method. The order of the operations/processes may be interchangeable.

Reference is made to FIGS. 3A and 3B. Shown there is an initial structure, the initial structure includes a substrate 102, a plurality of active regions E1 and E2 over the substrate 102, and an isolation structure 106 laterally surrounding the active regions E1 and E2. For example, the active regions E1 and E2 may be formed by patterning the substrate 102 by photolithography process. Then, an isolation layer maybe formed over the substrate 102, followed by an etching back process to form the isolation structure 106. In some embodiments, the active region E1 can be formed within the first conductivity type device region 101a, and the active region E2 can be formed within the second conductivity type device region 101b. In some embodiments, the active regions E1 and E2 can be fin structures protruding above the isolation structure 106 due to the etching back process that pull backs the isolation structure 106. In this way, the transistors formed on the active regions E1 and E2 are fin-type field effect transistors (FinFETs). However, in some other embodiments, the etching back process that pulls back the isolation structure 106 can be omitted, and thus the isolation structure 106 has a top surface substantially level with that of the active regions E1 and E2. In this way, the transistors formed on the active regions E1 and E2 are planar transistors.

A plurality of dummy gate structures DG can be formed over the substrate 100. In some embodiments, the dummy gate structures DG can be formed to extend across the active regions E1 and E2. Each of the dummy gate structures DG can include a gate dielectric layer 162 and a dummy gate 164. In some embodiments, the dummy gate structures DG may be formed by, for example, depositing a gate dielectric material and a dummy gate material over the substrate 100, followed by a patterning process to pattern the gate dielectric material and the dummy gate material to form the dummy gate structures DG. In some embodiments, the gate dielectric layer 162 may be, for example, silicon oxide, silicon nitride, a combination thereof, or the like, and may be deposited or thermally grown according to acceptable techniques. The gate dielectric layer 162 may be formed by suitable process, such as chemical vapor deposition (CVD), physical vapor deposition (PVD), atomic layer deposition (ALD), or any suitable process. In some embodiments, the dummy gate layer 164 may include polycrystalline-silicon (poly-Si) or poly-crystalline silicon-germanium (poly-SiGe). Further, the dummy gate layer 164 may be doped poly-silicon with uniform or non-uniform doping. The dummy gate layer 164 may be formed by suitable process, such as chemical vapor deposition (CVD), physical vapor deposition (PVD), atomic layer deposition (ALD), or any suitable process. In some embodiments, the dummy gate structure DG can be interchangeably referred to as a dummy gate, a dummy gate strip, a dummy gate layer, or a dummy gate pattern.

A plurality of gate spacers 120 are formed on opposite sidewalls of the dummy gate structures DG. The gate spacers 120 may be formed by, for example, depositing a spacer layer blanket over the dummy gate structures DG, followed by an etching process to remove horizontal portions of the spacer layer, such that vertical portions of the spacer layer remain on sidewalls of the dummy gate structures DG.

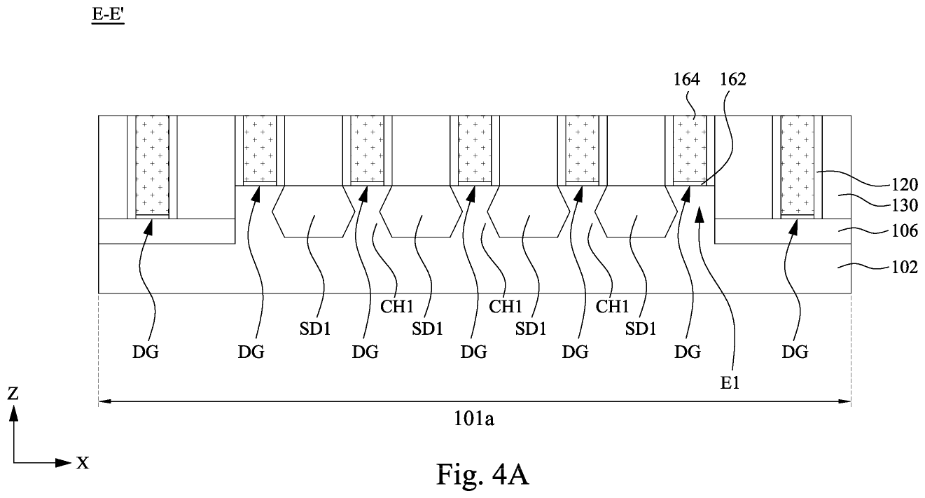

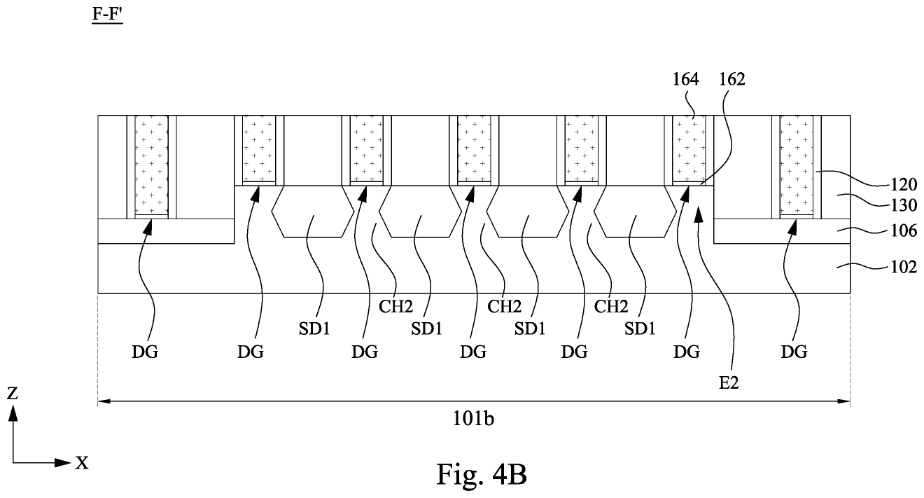

Reference is made to FIGS. 4A and 4B. A plurality of source/drain structures SD1 and SD2 are formed in the active regions E1 and E2. As an example in FIG. 4A, the active regions E1 and E2 exposed by the dummy gate structures DG and the gate spacers 120 is recessed by suitable process, such as etching. Afterwards, the source/drain structures SD1 are formed over the exposed surfaces of the remaining active region E1, and the source/drain structures SD2 are formed over the exposed surfaces of the remaining active region E2. In other words, the source/drain regions SD1 and SD2 can be formed in the active regions E1 and E2 and self-aligned to the gate spacers 120. Portions of the active regions E1 and E2 (i.e., fin-like structures) between the corresponding source/drain regions SD1/SD2 can serve as channel regions CH1 and CH2. The source/drain structures SD1 and SD2 may be formed by performing an epitaxial growth process that grows an epitaxy semiconductor material from the active region E1. The source/drain structures SD1/SD2 are doped with an n-type impurity (e.g., phosphorous) or a p-type impurity (e.g., boron), depending on the conductivity-type of the respective resulting transistors. In some embodiments, the source/drain structures SD1 can be doped with a first impurity (or first dopant), and the source/drain structures SD2 can be doped with a second impurity (or second dopant) having an opposite conductivity type to the first impurity. By way of example and not limitation, the source/drain structures SD1 can be doped with an n-type impurity, and the source/drain structures SD2 can be doped with a p-type impurity.

An interlayer dielectric layer (ILD) 130 is formed adjacent to the gate spacers 120. For example, a dielectric layer is deposited blanket over the substrate 102 and filling the spaces between the gate spacers 120, followed by a CMP process to remove excessive material of the dielectric layer until the top surfaces of the dummy gate structures DG are exposed.

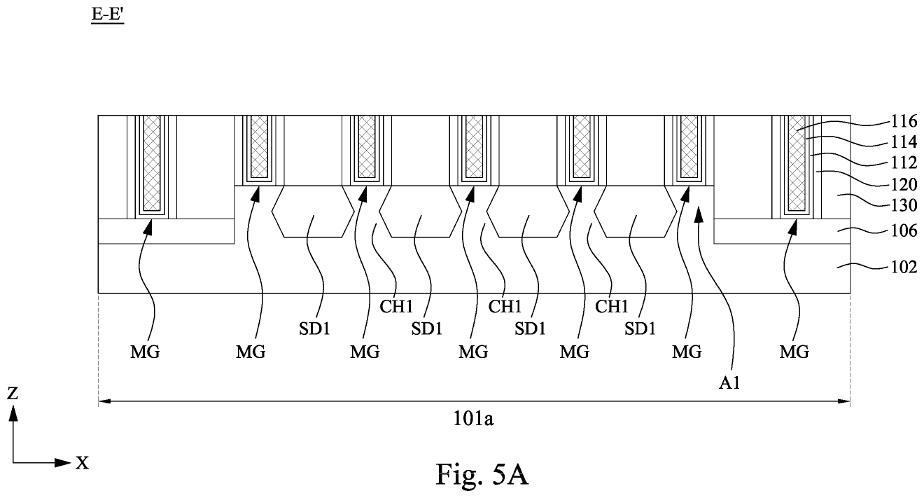

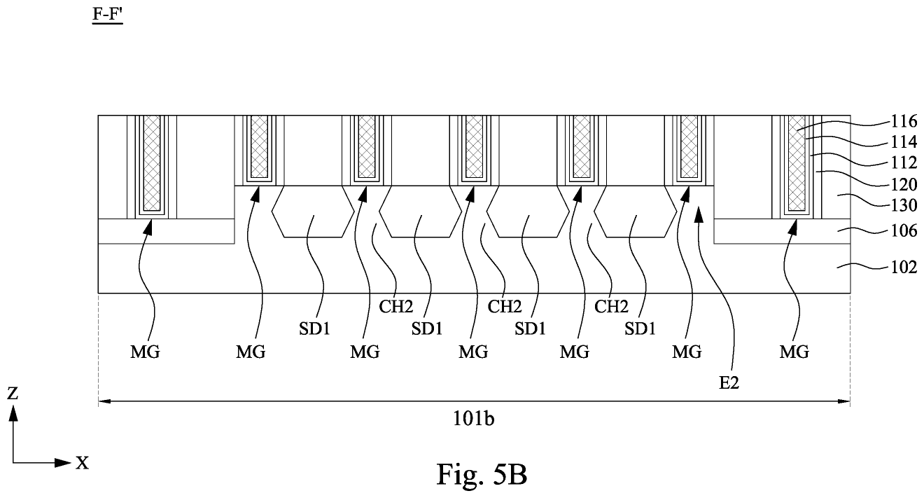

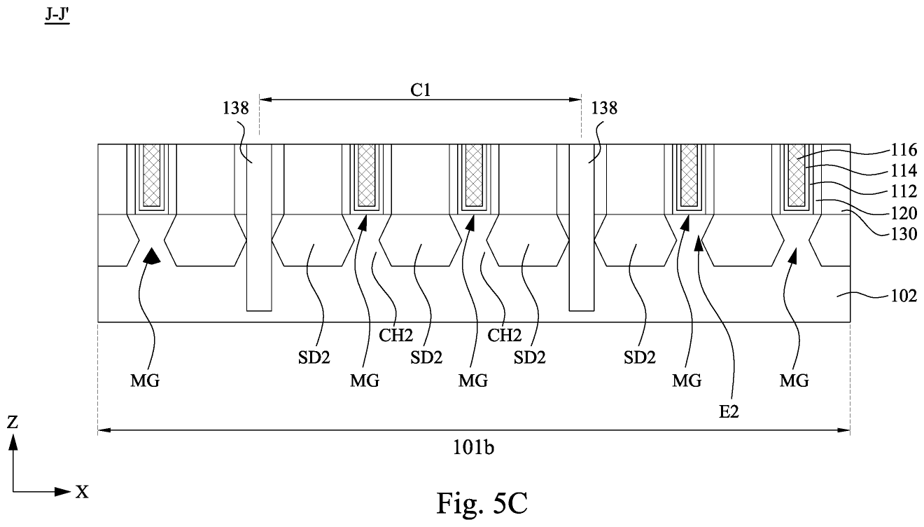

Reference is made to FIGS. 5A and 5B. The dummy gate structures DG are replaced with gate strips MG. In some embodiments, each of the gate strips MG may include a gate dielectric layer 112, a work function metal layer 114, and a filling metal 116. For example, the dummy gate structures DG are removed by an etching process to form gate trenches between the gate spacers 120, a gate dielectric material, a work function metal material, and a conductive material are formed sequentially in the gate trenches, followed by a CMP process to remove excessive materials of the gate dielectric material, the work function metal material, and the conductive material until the ILD layer 130 is exposed. In some embodiments, the gate strip MG can be interchangeably referred to as a gate, metal gate, a gate structure, a gate layer, or a gate pattern.

Reference is made to FIGS. 6A and 6B. Source/drain contacts 132 can be formed in the ILD layer 130 and over the source/drain regions SD1 and SD2. A dielectric region 134 (see FIG. 1C) can be formed over the source/drain regions SD1 and SD2 to separate the source/drain contacts 132 (see FIGS. 1C, 6A, and 6B). In some embodiments, the dielectric region 134 can be a metal-like defined region (MD)-cut structure for forming the source/drain contact 132, and the MD-cut structure can be formed by a cut metal-like defined region (CMD) process. Adjacent two of the source/drain contacts 132 can be spaced apart from each other by the dielectric region 134. In some embodiments, the dielectric region 134 further extend to cut the metal gate strips MG to form metal gate structures MG1 within the first conductivity type device region 101a and metal gate structures MG2 within the second conductivity type device region 101b.

Therefore, the transistors T0, T1, and T2 can be formed in the first conductivity type device region 101a, and the transistors T31, T32, T33 can be formed in the second conductivity type device region 101b. The transistors T31, T32, T33 can have an opposite conductivity type to the transistors T0, T1, and T2. For example, the transistors T31, T32, T33 can be PMOS transistors, while the transistors T0, T1, and T2 can be NMOS transistors. Specifically, each of the transistors T0, T1, and T2 can include the channel region CH1, the source/drain structures SD1 at opposite sides of the channel region CH1, and the metal gate structure MG1 around the channel region CH1. Each of the transistors T31, T32, T33 can include the channel region CH2, the source/drain structures SD2 at opposite sides of the channel region CH2, and the metal gate structure MG2 around the channel region CH2.

Subsequently, an interconnect structure 135 can be formed over the metal gate structures MG1 and MG2. Specifically, the interconnect structure 135 can be formed to have source/drain vias VD connecting to the source/drain contacts 132. The interconnect structure 135 may further include, for example, a plurality of metallization layers M0, M1, M2 . . . . My, with a plurality of layers of metallization vias (or interconnects) 136, connecting adjacent two of the metallization layers M0, M1, M2 . . . . My, and the source/drain vias VD are connected to the corresponding metallization layers M0. In some embodiments, the source/drain contacts 132, the metallization layers M0, M1, M2 . . . . My, and/or the metallization vias 136 may include a metal-containing material such as titanium nitride, titanium oxide, tungsten, cobalt, ruthenium, aluminum, copper, combinations thereof, multi-layers thereof, or the like. Also included in the interconnect structure 135 is an inter-metal dielectric (IMD) layer 9. The IMD layer 137 may provide electrical insulation as well as structural support for the various features in the interconnect structure 135.

Reference is made to FIGS. 5C and 6C. FIGS. 5C and 6C illustrate schematic views of intermediate stages in the manufacturing of a memory device in accordance with some embodiments. FIGS. 5C and 6C illustrate cross-sectional views obtained from reference cross-section J-J′ in FIG. 1G and correspond to FIGS. 5B and 6B, respectively. The steps preceding FIGS. 5C and 6C can correspond to those illustrated in FIGS. 3A-5B. For an understanding of the processes and structures involved up to this step, please refer to FIGS. 3A-5B. To avoid repetition, these preceding steps will not be reiterated in this section. While FIGS. 5C and 6C show an embodiment of the memory device with different layout profiles than the memory device in FIGS. 3A-5B, 6A, and 6B, the present disclosure may repeat reference numerals and/or letters in the various examples. This repetition is for the purpose of simplicity and clarity and does not in itself dictate a relationship between the various embodiments and/or configurations discussed.

As shown in FIG. 5C, the metal gate structures MG2 on the boundary of the OTP memory cell C1 can be removed to form isolation regions separating the source/drain regions of neighboring semiconductor devices from each other and separate different semiconductor devices. The isolation region may be formed by using an etching process. In the etching process, the metal gate structures MG1/MG2 on the boundary of the OTP memory cell C1 can be etched anisotropically, until the underlying active region E1/E2 is exposed. The etching may be stopped on the isolation structure 106. In some embodiments, the active region E1/E2 is then etched, and the etching continues down into the underlying substrate 102.

Subsequently, a dielectric material is filled in the isolation region (i.e., spaces originally occupied by the metal gate structures MG1/MG2) to form CPODE structures 138. As shown in FIG. 1G, the CPODE structures 138 extend in the Y-direction and being dummy gates. The metal gate structures MG1/MG2 are arranged between the CPODE structures 138. The material of the CPODE structures 138 is different from that of the metal gate structures MG1/MG2. In some embodiments, the CPODE structures 138 can be made of silicon oxide (SiOₓ), silicon nitride (SiₓN_{y}), silicon oxynitride (SiON), dielectric material(s), other suitable material, or a combination thereof. In some embodiments, the CPODE structures 138 can be formed by a deposition process, such as chemical vapor deposition (CVD), physical vapor deposition (PVD), atomic layer deposition (ALD), high density plasma CVD (HDPCVD), metal organic CVD (MOCVD), or plasma enhanced CVD (PECVD).

As shown in FIG. 6C, the substrate 102 may be removed from a back-side of thereof in a plurality of process operations, for example, CMP, HNA, and/or TMAH etching, which may be stop at the active regions E1 and E2, the source/drain structures SD1 and SD2, or the isolation structure 106. After the removal process, the active regions E1 and E2, the source/drain structures SD1 and SD2, or the isolation structure 106 can be exposed. Subsequently, a back-side insulation layer 139 can be formed over the active regions E1 and E2. In some embodiments, the back-side insulation layer 139 may formed over the CPODE structures 138 and laterally extends past the CPODE structures 138. In some embodiments, the back-side insulation layer 139 may formed to laterally extend from a bottom end of one the CPODE structures 138 to a bottom end of another one of the CPODE structures 138, such that the back-side insulation layer 139 may have a back-side surface level with back-side surfaces of the CPODE structures 138. In some embodiments, the back-side insulation layer 139 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

A back-side interconnect structure 140 can formed over the back-side insulation layer 139. The back-side interconnect structure includes a plurality of metallization layers with a plurality of metallization vias (or interconnects). The metal line illustrated here just for an example, and the metal line may be otherwise oriented (rotated 90 degrees or at other orientations). The back-side interconnect structure 140 may include power supply voltage lines 142 in back-side metallization layers formed in an inter-metal dielectric (IMD) layer 144. The power supply voltage lines 142 can be electrically connected to the source/drain regions SD1 and SD2. In some embodiments, materials of the power supply voltage lines 142 may include titanium nitride, titanium oxide, tungsten, cobalt, ruthenium, aluminum, copper, combinations thereof, multi-layers thereof, or the like, or any combinations thereof. In some embodiments, the IMD layer 144 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, the power supply voltage line 142 can be interchangeably referred to as a super-power-rail.

Reference is made to FIGS. 7A-7D. FIG. 7A illustrates a schematic circuit diagram of memory devices 200 and 200a in accordance with some embodiments. FIG. 7B illustrates a schematic circuit diagram of a memory device 200′ in accordance with some embodiments. FIGS. 7C and 7D illustrate top views of memory devices 200 and 200a in accordance with some embodiments. While FIGS. 7A-7D show embodiments of the memory devices with different circuit configurations and corresponding layout profiles than the memory device 100 and 100a in FIGS. 1A-1J, the present disclosure may repeat reference numerals and/or letters in the various examples. This repetition is for the purpose of simplicity and clarity and does not in itself dictate a relationship between the various embodiments and/or configurations discussed.

As shown in FIG. 7A, the difference between the embodiment in FIG. 7A and the embodiment in FIG. 1A is in that the OTP memory cell C2 in the memory device 200 can be in the dual side configuration. The adjacent OTP memory cells C2 can share the same bit line, which in turn optimizes space utilization within the memory array, and this architecture can be characterized by two variations, in which a first one (see FIG. 7C) is without CPODE Structure 138 and a second one (see FIG. 7D) is with CPODE structure 138. In some embodiments, the OTP memory cell C2 shown in FIG. 7A with dual side configuration can include 3 NMOS transistors and 1 set of PMOS transistors (e.g., including at least one PMOS transistor). For example, the OTP memory cell C2 can include the NMOS transistors T0, T1, and T2 and the PMOS transistor T3.

As shown in FIG. 7B, an OTP memory cell C2′ is similar to the OTP memory cell C2 as shown in FIG. 7A. The difference between the OTP memory cell C2′ and the OTP memory cell C2 is that the OTP memory cell C2′ can include more select transistors (e.g., 1-99) compared to FIG. 7A, enabling more complex memory operations or provide access to a larger array of memory cells. Additionally, corresponding to the number of select transistors, there are additional word lines in FIG. 7B. Each of these word lines is connected to the gate of the select transistors, allowing for individual or group control of rows or columns of memory cells, providing enhanced flexibility and control in memory operations. Therefore, with more select transistors and word lines, the structure in FIG. 7B can support more complex operations, such as selective programming, erasing, or reading of memory cells. In some embodiments, the OTP memory cell C2′ can omit to arrange the transistor used to relax the voltage stress as the transistor T1 as shown in FIG. 7A.

FIGS. 7C and 7D both reflect the schematic circuit diagram shown in FIG. 7A. As shown in FIG. 7C, the layout can exclude the CPODE structure 138. A cell width W2 of the OTP memory cell C2 in FIG. 7C can be defined as being about greater than or equal to 5 contact poly pitch (CPP, i.e., gate pitch), indicating the size and spacing considerations in the memory cell design. As shown in FIG. 7D, the layout can incorporate the CPODE structure 138. A cell width W2a of the OTP memory cell C2 in FIG. 7D can be defined as being about greater than or equal to 3.5 contact poly pitch (CPP, i.e., gate pitch), indicating the size and spacing considerations in the memory cell design. In some embodiments, the cell width W2a (see FIG. 7D) can be narrower than the cell width W2 (see FIG. 7C).

Reference is made to FIGS. 8A-8C. FIG. 8A illustrates a schematic circuit diagram of memory devices 300 and 300a in accordance with some embodiments. FIGS. 8B and 8C illustrate top views of memory devices 300 and 300a in accordance with some embodiments. While FIGS. 8A-8C show embodiments of the memory devices with different circuit configurations and corresponding layout profiles than the memory device 100 and 100a in FIGS. 1A-1J, the present disclosure may repeat reference numerals and/or letters in the various examples. This repetition is for the purpose of simplicity and clarity and does not in itself dictate a relationship between the various embodiments and/or configurations discussed.

As shown in FIG. 8A, the difference between the embodiment in FIG. 8A and the embodiment in FIG. 1A is in that the OTP memory cell C3 in the memory device 300 omits the transistor T1. The OTP memory cell C3 in memory device 300 can be configured to a single side configuration. Individual OTP memory cells C3 can operate with their distinct bit lines, and this architecture can be characterized by two variations, in which a first one (see FIG. 8B) is without CPODE Structure 138 and a second one (see FIG. 8C) is with CPODE structure 138. Specifically, the OTP memory cell C2 shown in FIG. 8A with single side configuration can include 2 NMOS transistors and 1 set of PMOS transistors (e.g., including at least one PMOS transistor). For example, the OTP memory cell C3 can include the NMOS transistors T0 and T2 and the FIGS. 8B and 8C both reflect the schematic circuit diagram shown in FIG. 8A. As shown in FIG. 8B, the layout can exclude the CPODE structure 138. A cell width W3 of the OTP memory cell C3 in FIG. 8B can be defined as being about greater than or equal to 6 contact poly pitch (CPP, i.e., gate pitch), indicating the size and spacing considerations in the memory cell design. As shown in FIG. 8C, the layout can incorporate the CPODE structure 138. A cell width W3a of the OTP memory cell C3 in FIG. 8C can be defined as being about greater than or equal to 3 contact poly pitch (CPP, i.e., gate pitch), indicating the size and spacing considerations in the memory cell design. In some embodiments, the cell width W3a (see FIG. 8C) can be narrower than the cell width W3 (see FIG. 8B).

Reference is made to FIGS. 9A-9C. FIG. 9A illustrates a schematic circuit diagram of memory devices 400 and 400a in accordance with some embodiments. FIGS. 9B and 9C illustrate top views of the memory devices 400 and 400a in accordance with some embodiments. While FIGS. 9A-9C show embodiments of the memory devices with different circuit configurations and corresponding layout profiles than the memory device 100 and 100a in FIGS. 1A-1J, the present disclosure may repeat reference numerals and/or letters in the various examples. This repetition is for the purpose of simplicity and clarity and does not in itself dictate a relationship between the various embodiments and/or configurations discussed.

As shown in FIG. 9A, the difference between the embodiment in FIG. 9A and the embodiment in FIG. 1A is in that the OTP memory cell C4 in the memory device 400 can be in the dual side configuration and omit the transistor T1. The adjacent OTP memory cells C4 can share the same bit line, which in turn optimizes space utilization within the memory array, and this architecture can be characterized by two variations, in which a first one (see FIG. 9B) is without CPODE Structure 138 and a second one (see FIG. 9C) is with CPODE structure 138. In some embodiments, the OTP memory cell C4 shown in FIG. 9A with dual side configuration can include 2 NMOS transistors and 1 set of PMOS transistors (e.g., including at least one PMOS transistor). For example, the OTP memory cell C4 can include the NMOS transistors T0 and T2 and the PMOS transistor T3.

FIGS. 9B and 9C both reflect the schematic circuit diagram shown in FIG. 9A. As shown in FIG. 9B, the layout can exclude the CPODE structure 138. A cell width W4 of the OTP memory cell C4 in FIG. 9B can be defined as being about greater than or equal to 4 contact poly pitch (CPP, i.e., gate pitch), indicating the size and spacing considerations in the memory cell design. As shown in FIG. 9C, the layout can incorporate the CPODE structure 138. A cell width W4a of the OTP memory cell C4 in FIG. 9C can be defined as being about greater than or equal to 2.5 contact poly pitch (CPP, i.e., gate pitch), indicating the size and spacing considerations in the memory cell design. In some embodiments, the cell width W4a (see FIG. 9C) can be narrower than the cell width W4 (see FIG. 9B).

Reference is made to FIGS. 10A-10C. FIG. 10A illustrates a schematic circuit diagram of memory device 500 and 500a in accordance with some embodiments. FIGS. 10B and 10C illustrate top views of the memory devices 500 and 500a in accordance with some embodiments. While FIGS. 10A-10C show embodiments of the memory devices with different circuit configurations and corresponding layout profiles than the memory device 100 and 100a in FIGS. 1A-1J, the present disclosure may repeat reference numerals and/or letters in the various examples. This repetition is for the purpose of simplicity and clarity and does not in itself dictate a relationship between the various embodiments and/or configurations discussed.

As shown in FIG. 10A, the difference between the embodiment in FIG. 10A and the embodiment in FIG. 1A is in that the OTP memory cell C5 in the memory device 500 omits the transistors T1 and T2. The OTP memory cell C5 in memory device 500 can be configured to a single side configuration. Individual OTP memory cells C5 can operate with their distinct bit lines, and this architecture can be characterized by two variations, in which a first one (see FIG. 10B) is without CPODE Structure 138 and a second one (see FIG. 10C) is with CPODE structure 138. Specifically, the OTP memory cell C5 shown in FIG. 10A with single side configuration can include 1 NMOS transistors and 1 set of PMOS transistors (e.g., including at least one PMOS transistor). For example, the OTP memory cell C5 can include the NMOS transistor T0 and the FIGS. 10B and 10C both reflect the schematic circuit diagram shown in FIG. 10A. As shown in FIG. 10B, the layout can exclude the CPODE structure 138. A cell width W5 of the OTP memory cell C5 in FIG. 10B can be defined as being about greater than or equal to 5 contact poly pitch (CPP, i.e., gate pitch), indicating the size and spacing considerations in the memory cell design. As shown in FIG. 10C, the layout can incorporate the CPODE structure 138. A cell width W5a of the OTP memory cell C5 in FIG. 10C can be defined as being about greater than or equal to 2 contact poly pitch (CPP, i.e., gate pitch), indicating the size and spacing considerations in the memory cell design. In some embodiments, the cell width W5a (see FIG. 10C) can be narrower than the cell width W5 (see FIG. 10B).

Reference is made to FIGS. 11A-11D. FIG. 11A illustrates a schematic circuit diagram of memory devices 600 and 600a in accordance with some embodiments. FIG. 11B illustrates a schematic circuit diagram of a memory device 600′ in accordance with some embodiments. FIGS. 11C and 11D illustrate top views of memory devices 600 and 600a in accordance with some embodiments. While FIGS. 11A-11D show embodiments of the memory devices with different circuit configurations and corresponding layout profiles than the memory device 100, and 100a in FIGS. 1A-1J, the present disclosure may repeat reference numerals and/or letters in the various examples. This repetition is for the purpose of simplicity and clarity and does not in itself dictate a relationship between the various embodiments and/or configurations discussed.

As shown in FIG. 11A, the difference between the embodiment in FIG. 9A and the embodiment in FIG. 1A is in that the OTP memory cell C6 in the memory device 600 can be in the dual side configuration and omit the transistors T1 and T2. The adjacent OTP memory cells C6 can share the same bit line, which in turn optimizes space utilization within the memory array, and this architecture can be characterized by two variations, in which a first one (see FIG. 11C) is without CPODE Structure 138 and a second one (see FIG. 11D) is with CPODE structure 138. In some embodiments, the OTP memory cell C4 shown in FIG. 11A with dual side configuration can include 1 NMOS transistors and 1 set of PMOS transistors (e.g., including at least one PMOS transistor). For example, the OTP memory cell C6 can include the NMOS transistor TO and the PMOS transistor T3.

As shown in FIG. 11B, an OTP memory cell C6′ is similar to the OTP memory cell C6 as shown in FIG. 11A. The difference between the OTP memory cell C6′ and the OTP memory cell C6 is that the OTP memory cell C6′ can include more select transistors (e.g., 1-99) compared to FIG. 11A, enabling more complex memory operations or provide access to a larger array of memory cells. Additionally, corresponding to the number of select transistors, there are additional word lines in FIG. 11B. Each of these word lines is connected to the gate of the select transistors, allowing for individual or group control of rows or columns of memory cells, providing enhanced flexibility and control in memory operations. Therefore, with more select transistors and word lines, the structure in FIG. 7B can support more complex operations, such as selective programming, erasing, or reading of memory cells. In some embodiments, the OTP memory cell C6′ can omit to arrange the transistor used to relax the voltage stress as the transistor T1 as shown in FIG. 11A.

FIGS. 11C and 11D both reflect the schematic circuit diagram shown in FIG. 11A. As shown in FIG. 11C, the layout can exclude the CPODE structure 138. A cell width W6 of the OTP memory cell C6 in FIG. 11C can be defined as being about greater than or equal to 4 contact poly pitch (CPP, i.e., gate pitch), indicating the size and spacing considerations in the memory cell design. As shown in FIG. 11C, the layout can incorporate the CPODE structure 138. A cell width W6a of the OTP memory cell C6 in FIG. 11D can be defined as being about greater than or equal to 2.5 contact poly pitch (CPP, i.e., gate pitch), indicating the size and spacing considerations in the memory cell design. In some embodiments, the cell width W6a (see FIG. 11D) can be narrower than the cell width W6 (see FIG. 11C).

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a memory bit cell with an additional PMOS transistor therein. This structure with both NMOS and PMOS transistors can introduce a balanced ratio of PMOS/NMOS in bit cell array, achieving a more balanced distribution of transistor types and enhancing the overall stability and uniformity of the memory cell's electrical characteristics. Additionally, the introduction of PMOS transistors can create multiple potential breakdown paths during the programming process, which in turn increases the likelihood of successful programming, as it provides alternative routes for breakdown if one path fails. Furthermore, in super-power-rail (SPR) processes, the connected poly on oxide definition (OD) edge (CPODE) structure can introduce in MOSFETs to isolate the substrate, mitigating leakage issues. This isolation not only prevents the substrate leakage on neighboring bit cells but also contributes to higher overall performance in SPR processes.

In some embodiments, a method includes forming a first select transistor of a first one-time programmable (OTP) memory bit cell over a substrate, wherein the first select transistor is of a first conductivity type; forming a first anti-fuse transistor of the first OTP memory bit cell over the substrate, wherein the first anti-fuse transistor is of a second conductivity type opposite to the first conductivity type; forming a bit line over the substrate, wherein the bit line is electrically coupled to a source/drain terminal of the first select transistor. In some embodiments, the first select transistor is an n-type metal-oxide-semiconductor transistor, and the first anti-fuse transistor is a p-type metal-oxide-semiconductor transistor. In some embodiments, the method further includes forming a second anti-fuse transistor over the substrate, wherein the second anti-fuse transistor is of the second conductivity type and connected in parallel to the first anti-fuse transistor. In some embodiments, the first select transistor is between the first and second anti-fuse transistors from a top view. In some embodiments, the method further includes forming a third anti-fuse transistor over the substrate, wherein the third anti-fuse MOS transistor is of the second conductivity type and connected in parallel to the first and second anti-fuse transistors. In some embodiments, the method further includes forming a second anti-fuse transistor over the substrate, wherein the second anti-fuse transistor is of the first conductivity type and connected in parallel to the first anti-fuse transistor. In some embodiments, the first anti-fuse transistor is between the first select transistor and the second anti-fuse transistor from a top view. In some embodiments, the method further includes forming a second select transistor of the first OTP memory bit cell over the substrate, wherein the second select transistor is of the first conductivity type. In some embodiments, the method further includes forming a second OTP memory bit cell over the substrate, wherein the second OTP memory bit comprises a second select transistor and a second anti-fuse transistor, and a source/drain terminal of the second select transistor is electrically coupled to the bit line. In some embodiments, the second select transistor is of the first conductivity type, and the second anti-fuse transistor is of the second conductivity type.

In some embodiments, a method includes forming a first active region over a substrate, and a second active region over the substrate; forming a plurality of first source/drain regions on the first active region, and a plurality of second source/drain regions on the second active region; forming a first gate structure around the first active region and between the first source/drain regions, wherein the first gate structure forms an n-type metal-oxide-semiconductor (NMOS) transistor with the first source/drain regions, and the NMOS transistor is of the one-time programmable (OTP) memory bit cell; forming a second gate structure around the second active region and between the second source/drain regions, wherein the second gate structure forms a p-type metal-oxide-semiconductor (PMOS) transistor with the second source/drain regions, and the PMOS transistor is of the OTP memory bit cell. In some embodiments, the PMOS transistor is of an anti-fuse transistor. In some embodiments, the NMOS transistor is of a select transistor or an anti-fuse transistor. In some embodiments, the method further includes forming an isolation structure laterally surrounding the first and second active regions. In some embodiments, the method further includes forming first and second dielectric structures extending along lengthwise directions of the first and second gate structures and downwardly to cut through the second active region, wherein the PMOS transistor is between the first and second dielectric structures. In some embodiments, the method further includes forming an insulation layer extending from a bottom end of the first dielectric structure to a bottom end of the second dielectric structure.

In some embodiments, a semiconductor structure includes a substrate, a select n-type metal-oxide-semiconductor (NMOS) transistor, a programming NMOS transistor, and a first programming p-type metal-oxide-semiconductor (PMOS) transistor. The select NMOS is over the substrate. The programming NMOS transistor is over the substrate. The first programming p-type metal-oxide-semiconductor (PMOS) transistor is over the substrate. The select NMOS transistor, the programming NMOS transistor, and the programming PMOS transistor form an one-time programmable (OTP) memory bit cell. In some embodiments, a gate terminal of the first programming PMOS transistor is electrically coupled to one of source/drain terminals of the programming NMOS transistor. In some embodiments, the semiconductor structure further includes a programming word line electrically coupled to one of source/drain terminals of the programming PMOS transistor and a gate terminal of the programming NMOS transistor. In some embodiments, the semiconductor structure further includes a second programming PMOS transistor over the substrate, wherein the second programming PMOS transistor is electrically connected in parallel to the first programming PMOS transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first select transistor of a first one-time programmable (OTP) memory bit cell over a substrate, wherein the first select transistor is of a first conductivity type;
forming a first anti-fuse transistor of the first OTP memory bit cell over the substrate, wherein the first anti-fuse transistor is of a second conductivity type opposite to the first conductivity type; and
forming a bit line over the substrate, wherein the bit line is electrically coupled to a source/drain terminal of the first select transistor.

2. The method of claim 1, wherein the first select transistor is an n-type metal-oxide-semiconductor transistor, and the first anti-fuse transistor is a p-type metal-oxide-semiconductor transistor.

3. The method of claim 1, further comprising:
forming a second anti-fuse transistor over the substrate, wherein the second anti-fuse transistor is of the second conductivity type and connected in parallel to the first anti-fuse transistor.

4. The method of claim 3, wherein the first select transistor is between the first and second anti-fuse transistors from a top view.

5. The method of claim 3, further comprising:
forming a third anti-fuse transistor over the substrate, wherein the third anti-fuse transistor is of the second conductivity type and connected in parallel to the first and second anti-fuse transistors.

6. The method of claim 1, further comprising:
forming a second anti-fuse transistor over the substrate, wherein the second anti-fuse transistor is of the first conductivity type and connected in parallel to the first anti-fuse transistor.

7. The method of claim 6, wherein the first anti-fuse transistor is between the first select transistor and the second anti-fuse transistor from a top view.

8. The method of claim 1, further comprising:
forming a second select transistor of the first OTP memory bit cell over the substrate, wherein the second select transistor is of the first conductivity type.

9. The method of claim 1, further comprising:
forming a second OTP memory bit cell over the substrate, wherein the second OTP memory bit comprises a second select transistor and a second anti-fuse transistor, and a source/drain terminal of the second select transistor is electrically coupled to the bit line.

10. The method of claim 9, wherein the second select transistor is of the first conductivity type, and the second anti-fuse transistor is of the second conductivity type.

11. A method, comprising:
forming a first active region over a substrate, and a second active region over the substrate;
forming a plurality of first source/drain regions on the first active region, and a plurality of second source/drain regions on the second active region;
forming a first gate structure around the first active region and between the first source/drain regions, wherein the first gate structure forms an n-type metal-oxide-semiconductor (NMOS) transistor with the first source/drain regions, and the NMOS transistor is of an one-time programmable (OTP) memory bit cell; and
forming a second gate structure around the second active region and between the second source/drain regions, wherein the second gate structure forms a p-type metal-oxide-semiconductor (PMOS) transistor with the second source/drain regions, and the PMOS transistor is of the OTP memory bit cell.

12. The method of claim 11, wherein the PMOS transistor is of an anti-fuse transistor.

13. The method of claim 11, wherein the NMOS transistor is of a select transistor or an anti-fuse transistor.

14. The method of claim 11, further comprising:
forming an isolation structure laterally surrounding the first and second active regions.

15. The method of claim 11, further comprising:
forming first and second dielectric structures extending along lengthwise directions of the first and second gate structures and downwardly to cut through the second active region, wherein the PMOS transistor is between the first and second dielectric structures.

16. The method of claim 15, further comprising:
forming an insulation layer extending from a bottom end of the first dielectric structure to a bottom end of the second dielectric structure.

17. A semiconductor structure, comprising:
a substrate;
a select n-type metal-oxide-semiconductor (NMOS) transistor over the substrate;
a programming NMOS transistor over the substrate; and
a first programming p-type metal-oxide-semiconductor (PMOS) transistor over the substrate, wherein the select NMOS transistor, the programming NMOS transistor, and the programming PMOS transistor form an one-time programmable (OTP) memory bit cell.

18. The semiconductor structure of claim 17, wherein a gate terminal of the first programming PMOS transistor is electrically coupled to one of source/drain terminals of the programming NMOS transistor.

19. The semiconductor structure of claim 18, further comprising:
a programming word line electrically coupled to one of source/drain terminals of the programming PMOS transistor and a gate terminal of the programming NMOS transistor.

20. The semiconductor structure of claim 17, further comprising:
a second programming PMOS transistor over the substrate, wherein the second programming PMOS transistor is electrically connected in parallel to the first programming PMOS transistor.
